(19) United States
(12) Patent Application Publication
(10) Pub. No.: US 2013/0140573 A1
(43) Pub. Date: Jun. 6, 2013

(54) MANUFACTURING METHOD FOR CRYSTALLINE SEMICONDUCTOR FILM, SEMICONDUCTOR DEVICE, AND DISPLAY DEVICE

(71) Applicant: Yoshinobu Nakamura, Osaka-shi (JP)

(72) Inventor: Yoshinobu Nakamura, Osaka-shi (JP)

(21) Appl. No.: 13/701,536

(22) PCT Filed: Mar. 29, 2011
(86) PCT No.: PCT/JP11/57879

§ 371 Date: Dec. 3, 2012

(30) Foreign Application Priority Data
Jun. 7, 2010 (JP) 2010-130039

(51) Int. Cl. H01L 29/786; H01L 21/02

(52) U.S. Cl. CPC H01L 29/786; H01L 21/02104
USPC 257/59; 438/486

(57) ABSTRACT

An object is to form a crystalline semiconductor film including a plurality of semiconductor regions with different average grain sizes by a simple manufacturing process.

The surface of a crystalline silicon film 30b is irradiated with a laser beam 5, to crystallize the crystalline silicon film 30b. At this time, in the crystalline silicon film 30b below which a gate electrode 21 and a radiation portion 22 having a large area are provided, part of generated heat energy escapes to the radiation portion 22, and hence the crystalline silicon film 30b is insufficiently melted. For this reason, a formed first silicon region 30c1 has a large average grain size. On the other hand, in the crystalline silicon film 30b below which agate electrode 71 having a small area is provided, generated heat is resistant to escaping, and hence the crystalline silicon film 30b is completely melted. Thereby, the second silicon region 30c2 has a small average grain size.

### TECHNICAL FIELD

The present invention relates to a manufacturing method for a crystalline semiconductor film, a semiconductor device, and a display device, and more specifically relates to a manufacturing method for a crystalline semiconductor film which is favorable for forming a plurality of kinds of semiconductor devices having different electric characteristics, a semiconductor device, and a display device.

### BACKGROUND ART

In recent years, electronic equipment, which has a circuit configured using a semiconductor device represented by a thin film transistor (hereinafter, referred to as a “TFT”), has come to be in broad use. Such a semiconductor device is formed using a silicon film having a film thickness of several tens of nm to several hundreds of nm and deposited on an insulating substrate by means of CVD (Chemical Vapor Deposition).

A liquid crystal display device is one of such electronic equipment, and for its liquid crystal panel, a full-monolithic panel comes to be used in which not only an image display portion is formed, but also peripheral circuits such as a drive circuit and a power supply circuit are formed in a picture-frame portion on the periphery of the image display portion. For the peripheral circuit of the liquid crystal panel as thus described, a TFT with a high carrier mobility and a large on-current has been required. On the other hand, for a switching device included in each pixel formation portion constituting the image display portion, a TFT with a small variation in threshold voltage has been required. Accordingly, among silicon films (hereinafter, referred to as “crystalline silicon films”) having crystalline structures, a crystalline silicon film with a large average grain size is suitable for formation of the TFT to constitute the peripheral circuit, and a crystalline silicon film with a small average grain size is suitable for formation of the TFT to be the switching device.

Further, a liquid crystal display device, provided with a function of detecting a touched position at the time of a viewer touching a display screen with his or her finger or a pen, also requires a photodiode that functions as a photosensor. For more accurate detection of the touched position, in the photodiode, a ratio (hereinafter, referred to as an “on/off ratio”) between an on-current in lighted time and an off-current in unlighted time is required to be large. For formation of such a photodiode, a crystalline silicon film with a small average grain size is suitable in order to make the off-current small and the on/off ratio large.

As thus described, formation of a plurality of kinds of semiconductor devices with different electric characteristics on the same insulating substrate requires formation of a crystalline silicon film, including at least two kinds of silicon regions with different average grain sizes, in predetermined positions on the insulating substrate.

Japanese Patent Application Laid-Open No. 2007-115786 discloses performing a crystallization step three times at the time of forming a crystalline silicon film from an amorphous silicon film deposited on the insulating substrate. Specifically, first in a first crystallization step, catalytic elements for promoting crystallization are added to an amorphous silicon film, which is then heat-treated, to form a crystalline silicon film. Next, in a second crystallization step, the crystalline silicon deposited in the first crystallization step is irradiated with a laser beam, to improve its crystallinity. Further, in a third crystallization step, a micro-crystalline region generated in the crystalline silicon film in the second crystallization step is irradiated with a laser beam, to be selectively re-crystallized. In such a manner, the crystalline silicon film with an excellent crystallinity is stably formed all over the insulating substrate.

Japanese Patent Application Laid-Open No. 2009-246235 discloses a method for forming a crystalline silicon film that has two silicon regions with different average grain sizes. Specifically, in a first crystallization step, a part of an amorphous silicon film deposited on an insulating substrate is crystallized, to form a first silicon region. In a second crystallization step, the remaining amorphous silicon film is melted and solidified, to form a second silicon region with a smaller average grain size than that of the first silicon region. In a third crystallization step, while holding the state of the first silicon region having a larger average grain size than the average grain size of the second silicon region, those are melted and solidified, to improve crystallinities of the first and second silicon regions. Thin film transistors with different electric characteristics are respectively formed in the two silicon regions as thus formed which have different average grain sizes and are included in the crystalline silicon film.

### PRIOR ART DOCUMENTS

### Patent Documents

[Patent Document 1] Japanese Patent Application Laid-Open No. 2007-115786

[Patent Document 2] Japanese Patent Application Laid-Open No. 2009-246235

### SUMMARY OF THE INVENTION

### Problems to be Solved by the Invention

However, the crystallization method described in Japanese Patent Application Laid-Open No. 2007-115786 is a crystallization method for stably forming a crystalline silicon film with a uniform average grain size all over the insulating substrate. Therefore, the crystalline silicon film as thus described does not include a plurality of silicon regions with different average grain sizes which can be formed with a plurality of semiconductor devices with different electric characteristics, such as a TFT with a large on-current and a TFT with a small variation in threshold voltage or a photodiode with a small off-current. When a plurality of kinds of semiconductor devices with different electric characteristics are formed in such a crystalline silicon film, at least any kind of semiconductor device cannot sufficiently exert its function.

Further, the crystallization method described in Japanese Patent Application Laid-Open No. 2009-246235 includes the three times of crystallization steps from the first crystallization step to the third crystallization step for forming a crystalline silicon film including two silicon regions with different average grain sizes. This makes the manufacturing process for the crystalline silicon film complicated, to increase its manufacturing cost.

Hence, an object of the present invention is to provide a manufacturing method for a crystalline semiconductor film, which can form a crystalline semiconductor film including a plurality of semiconductor regions with different average grain sizes by a simple manufacturing process. Further, another object of the present invention is to provide a semiconductor device and a display device in which a plurality of crystalline semiconductor films with different average grain sizes are used.

### Means for Solving the Problems

A first aspect is directed to a manufacturing method for a crystalline semiconductor film, to form crystalline semiconductor films including a plurality of semiconductor regions with different average grain sizes on an insulating substrate, the method being provided with:

a step of depositing a metal film on the insulating substrate;

a step of patterning the metal film to form a first metal pattern and a second metal pattern with a smaller area than that of the first metal pattern;

a step of depositing an insulating film so as to coat the first and second metal patterns;

a step of depositing an amorphous semiconductor film on the insulating substrate;

a first crystallization step of crystallizing the amorphous semiconductor film, to form a first crystalline semiconductor film; and

a second crystallization step of crystallizing the first crystalline semiconductor film, to form a second crystalline semiconductor film,

wherein the second crystalline semiconductor film includes a first semiconductor region located above the first metal pattern and having substantially the same average grain size as an average grain size of the first crystalline semiconductor film, and a second semiconductor region located above the second metal pattern and having a larger average grain size than the average grain size of the first semiconductor region.

A second aspect is such that in the first aspect,

the second crystallization step includes a step of irradiating the first crystalline semiconductor film with a laser beam.

A third aspect is such that in the first aspect,

the first metal pattern includes a third metal pattern, and a fourth metal pattern surrounding the third metal pattern.

A fourth aspect is such that in the second aspect,

a wavelength of the laser beam is from 126 to 370 nm.

A fifth aspect is such that in the second aspect, the laser beam is outputted from a pulse oscillating excimer laser.

A sixth aspect is such that in the second aspect,

the laser beam is a substantially linear beam, and

the second crystallization step is to step-scan the laser beam in a short-axial direction of a beam shape.

A seventh aspect is such that in the sixth aspect,

a width of the first metal pattern is larger than a length in the short-axial direction of the laser beam.

An eighth aspect is such that in the first aspect,

the first crystallization step includes a step of heating the amorphous semiconductor film at a predetermined temperature to be grown by solid phase epitaxy, so as to form the first crystalline semiconductor film.

A ninth aspect is such that in the eighth aspect,

the predetermined temperature is from 500 to 700° C.

A tenth aspect is such that in the eighth aspect,

the first crystallization step further includes a step of adding catalytic elements for promoting crystallization of the amorphous semiconductor film to the surface of the amorphous semiconductor film.

An eleventh aspect is such that in the tenth aspect,

the catalytic element contains at least one element selected from the group consisting of iron, cobalt, nickel, germanium, ruthenium, rhodium, palladium, osmium, iridium, platinum, copper, and gold.

A twelfth aspect is such that in the tenth aspect,

the step of adding the catalytic elements includes the step of forming a film that contains the catalytic element with a concentration of 1E10 to 1E12 atoms/cm² on the surface of the amorphous semiconductor film.

A thirteenth aspect is such that in any one of the first to twelfth aspects,

the amorphous semiconductor film is an amorphous silicon film, and

the first and second crystalline semiconductor films are crystalline silicon films.

A fourteenth aspect is such that in the first aspect,

the metal film contains refractory metal elements, the insulating film includes at least any of a silicon oxide film, a silicon nitride film, and a silicon oxynitride film.

A fifteenth aspect is directed to a semiconductor device provided with a thin film transistor in which the crystalline semiconductor film, formed by the manufacturing method for a crystalline semiconductor film according to the first aspect, serves as an active layer.

A sixteenth aspect is such that in the fifteenth aspect,

the crystalline semiconductor film includes a first semiconductor region, and a second semiconductor region having a smaller average grain size than that of the first semiconductor region,

the thin film transistor includes a first thin film transistor, and a second thin film transistor with different electric characteristics from those of the first thin film transistor, and

the first semiconductor region serves as an active layer in the first thin film transistor, and the second semiconductor region serves as an active layer in the second thin film transistor.

A seventeenth aspect is such that in the fifteenth aspect,

a photodiode is further provided,

the crystalline semiconductor film includes a first semiconductor region, and a second semiconductor region having a smaller average grain size than that of the first semiconductor region, and

the first semiconductor region serves as an active layer in the thin film transistor, and the second semiconductor region serves as an active layer in the photodiode.

An eighteenth aspect is such that in the seventeenth aspect,

the photodiode further includes a light blocking film made up of a metal pattern and formed in between the active layer and the insulating substrate.

A nineteenth aspect is directed to a display device provided with the semiconductor device according to the sixteenth aspect, an image display portion, and a peripheral circuit required for driving the image display portion, wherein

the peripheral circuit includes the first thin film transistor of the semiconductor device, and

the image display portion includes the second thin film transistor of the semiconductor device.

A twentieth aspect is such that in the nineteenth aspect,

the semiconductor device according to the seventeenth aspect and a photosensor are further provided, and

the photosensor includes the photodiode of the semiconductor device.

### Effects of the Invention

According to the first aspect of the present invention, in the first crystallization step, an amorphous semiconductor film is crystallized, to form a first crystalline semiconductor film. Next, in the second crystallization step, the first crystalline semiconductor film is melted and solidified, to form a second crystalline semiconductor film. At this time, the first crystalline semiconductor film above the first metal pattern with a large area is hardly melted, leading to improvement in its crystallinity, and it becomes a first semiconductor region. For this reason, an average grain size of the first semiconductor region hardly changes from, and is almost the same as, an average grain size of the first crystalline semiconductor film. On the other hand, the second crystalline semiconductor film above the second metal pattern with a small area is completely melted and solidified, and it becomes a second semiconductor region. For this reason, an average grain size of the second semiconductor region becomes smaller than average grain sizes of the first crystalline semiconductor film and the first semiconductor region. As thus described, according to the manufacturing method for a crystalline semiconductor film of the present invention, the first semiconductor region and the second semiconductor region with different average grain sizes can be simultaneously formed, thereby to simplify a manufacturing process for the semiconductor device. Further, since the second crystalline semiconductor film includes the first semiconductor region and the second semiconductor region with different average grain sizes, semiconductor devices with different electric characteristics can be respectively formed in the first and second semiconductor regions.

According to the second aspect of the present invention, in the second crystallization step, the first crystalline semiconductor film is irradiated with a laser beam, thereby to easily form the second crystalline semiconductor film including the first semiconductor region and the second semiconductor region.

According to the third aspect of the present invention, a first metal pattern is a pattern including a third metal pattern, and a fourth metal pattern formed so as to surround the third metal pattern, and having a large area and a large heat capacity. In the second crystallization step, energy of the laser beam, with which the first crystalline semiconductor film above the third and fourth metal patterns has been irradiated, is radiated by the third and fourth metal patterns. This prevents the first crystalline semiconductor film from being completely melted, thereby allowing improvement only in its crystallinity without a change in its average grain size.

According to the fourth aspect of the present invention, a laser beam with a wavelength of 126 to 370 μm, which is used in the second crystallization step, can provide large energy in an extremely short time of nanosecond to microsecond order, and is also apt to be absorbed in a semiconductor film since being light in an ultraviolet region. Therefore, irradiating the first crystalline semiconductor film with the laser beam with a wavelength of 126 to 370 μm can efficiently form the second crystalline semiconductor film including the first semiconductor region whose crystallinity has been improved without a change in its average grain size, and the second semiconductor region whose average grain size is smaller than that of the first semiconductor region.

According to the fifth aspect of the present invention, in the second crystallization step, step-scanning the laser beam, outputted from a pulse oscillating excimer laser, in a fixed direction can efficiently crystallize the first crystalline semiconductor film, so as to form the second crystalline semiconductor film.

According to the sixth aspect of the present invention, in the second crystallization step, a laser beam in a substantially linear shape is step-scanned in a short-axial direction of a beam shape. This can crystallize the first crystalline semiconductor film with a wide area in a short time, so as to form the second crystalline semiconductor film in an efficient and simple manner.

According to the seventh aspect of the present invention, the first metal pattern with a large area and a large heat capacity is expanded below the first crystalline silicon film that is irradiated with the laser beam. When a length of the first metal pattern is larger than a length in the short-axial direction of the laser beam, much of heat energy generated in the second crystalline silicon film at the time of irradiation with the laser beam escapes to the first metal pattern via an insulating film. This results in insufficient heating of the second crystalline silicon film above the first metal pattern, and hence the second crystalline silicon film is not completely melted. The average grain size of the first semiconductor region as thus formed hardly changes from, and is almost the same as, the average grain size of the second crystalline silicon film.

According to the eighth aspect of the present invention, in the first crystallization step, the amorphous semiconductor film is heated at a predetermined temperature to be grown by solid phase epitaxy. Therefore, the characteristics of the crystallized first crystalline semiconductor film can be improved while the first crystallization step is made more efficient.

According to the ninth aspect of the present invention, when the first crystallization step is performed at a temperature lower than 500° C., a solid phase epitaxy speed is very low, to cause a decrease in throughput. Further, when it is performed at a temperature higher than 700° C., the first crystalline semiconductor film can be obtained in which not only crystal particles with large grain sizes due to the catalytic elements have grown but also crystal particles with small grain sizes not due to the catalytic elements have grown. There are some cases where, when a semiconductor device is manufactured using a second crystalline semiconductor film obtained by further crystallizing the first crystalline semiconductor film as thus described, sufficient electric characteristics are not obtained. Thereat, performing the first crystallization step in a temperature range of 500 to 700° C. can prevent lowering of the solid phase epitaxy speed, and can also prevent deterioration in electric characteristics.

According to the tenth aspect of the present invention, adding catalytic elements to the surface of the amorphous semiconductor film can promote crystallization of the amorphous semiconductor film. This allows efficient formation of the first crystalline semiconductor film in the first crystallization step, and also allows improvement in characteristics of the crystallized first crystalline semiconductor film.

According to the eleventh aspect of the present invention, a film containing as the catalytic element an element selected from the group consisting of iron, cobalt, nickel, germanium, ruthenium, rhodium, palladium, osmium, iridium, platinum, copper, and gold is formed on the surface of the amorphous semiconductor film, and hence it is possible to efficiently perform formation of the first crystalline semiconductor film, and also improve the characteristics of the crystallized first crystalline semiconductor film.

According to the twelfth aspect of the present invention, when a film with a concentration of the catalytic elements being lower than 1E10 atoms/cm² is formed on the surface of the amorphous semiconductor film, crystallization of the amorphous semiconductor film does not occur at all, or even when the crystallization occurs, the solid phase epitaxy speed is very low. On the other hand, when a film with a concentration of the catalytic elements being higher than 1E12 atoms/cm² is formed, a density of the crystal grains due to the catalytic elements is high, but a grain size of the crystal grain not due to the catalyst density is small, leading to deterioration in electric characteristics. Thereat, making the concentration of the catalytic elements be 1E10 to 1E12 atoms/cm² can prevent lowering of the solid phase epitaxy speed, and can also prevent deterioration in electric characteristics.

According to the thirteenth aspect of the present invention, since the amorphous semiconductor film is an amorphous silicon film, it can be easily deposited. Further, since the first and second amorphous semiconductor films are crystalline silicon films, they can be easily crystallized.

According to the fourteenth aspect of the present invention, since the metal film contains refractory metal elements, the metal film is not melted in the first and second crystallization steps. It is thereby possible to easily form the second crystalline semiconductor film including the first semiconductor region and the second semiconductor region. Further, a silicon oxide film, a silicon nitride film, and a silicon oxynitride film are not denatured in the first and second crystallization steps. For this reason, these films function as insulating films even after the first and second crystallization steps.

According to the fifteenth aspect of the present invention, it is possible to forma thin film transistor in which the crystalline semiconductor film formed by the manufacturing method for a crystalline semiconductor film according to the first aspect serves as an active layer.

According to the sixteenth aspect of the present invention, an average grain size of the crystal grain contained in the first semiconductor region of the second crystalline semiconductor film formed in accordance with the fifteenth aspect is larger than an average grain size of the crystal grain contained in the second semiconductor region. Thereat, in the first thin film transistor with the first semiconductor region serving as the active layer, a carrier mobility is high, and its operation speed can be made high. Further, in the second thin film transistor with the second semiconductor region serving as the active layer, a variation in threshold voltage can be made small. As thus described, separately forming the thin film transistors with different electric characteristics in the first semiconductor region and the second semiconductor region can sufficient exert the ability of each thin film transistor.

According to the seventeenth aspect of the present invention, forming a photodiode in the second semiconductor region with a small average grain size can increase an on/off ratio of the photodiode. This can increase the sensitivity of the photodiode.

According to the eighteenth aspect of the present invention, in the photodiode, a light blocking film is formed between the active layer and the insulating substrate. This can block light that is directly incident on the photodiode from the insulating substrate side, to make high the sensitivity of the photodiode to light that is incident from the surface side.

According to the nineteenth aspect of the present invention, since the peripheral circuit is configured using the first thin film transistor formed in the first semiconductor region, the operation speed of the peripheral circuit can be made high. This results in reduction in circuit scale of the peripheral circuit, and hence it is possible to narrow a picture-frame portion of the display panel, so as to reduce the display panel in size, as well as promoting high performance and high image quality of the display device. Further, since the image display portion is formed using the second thin film transistor formed in the second semiconductor region, variations in brightness and color of an image displayed in the image display portion can be made small. This can stabilize display of the display device.

According to the twentieth aspect of the present invention, similarly to the nineteenth aspect, the operation speed of the peripheral circuit can be made high. This results in reduction in circuit scale of the peripheral circuit, and hence it is possible to narrow a picture-frame portion of the display panel, so as to reduce the display panel in size, as well as promoting high performance and high image quality of the display device. Further, since the on/off ratio of the photodiode is large, a touched position can be accurately detected.

### BRIEF DESCRIPTION OF THE DRAWINGS

FIG. 1 is a sectional view showing a configuration of a semiconductor device according to a first embodiment of the present invention.

FIGS. 2(A) to 2(C) are step sectional views showing respective manufacturing steps for the semiconductor device shown in FIG. 1.

FIGS. 3(A) to 3(C) are step sectional views showing respective manufacturing steps for the semiconductor device shown in FIG. 1.

FIGS. 4(A) to 4(C) are step sectional views showing respective manufacturing steps for the semiconductor device shown in FIG. 1.

FIGS. 5(A) and 5(B) are step sectional views showing respective manufacturing steps for the semiconductor device shown in FIG. 1.

FIG. 6 is a plan view showing a manufacturing step for the semiconductor device which corresponds to FIG. 2(B).

FIG. 7 is a plan view showing a manufacturing step for the semiconductor device which corresponds to FIG. 4(A).

FIG. 8 is a plan view showing first and second silicon regions formed by a manufacturing step for the semiconductor device which corresponds to FIG. 4(A).

FIG. 9 is a plan view showing a manufacturing step for the semiconductor device which corresponds to FIG. 4(B).

FIG. 10 is a plan view showing a manufacturing step for the semiconductor device which corresponds to FIG. 4(C).

FIG. 11 is a plan view showing a manufacturing step for the semiconductor device which corresponds to FIG. 5(A).

FIG. 12 is a sectional view showing a configuration of a semiconductor device according to a second embodiment of the present invention.

FIGS. 13(A) to 13(C) are step sectional views showing respective manufacturing steps for the semiconductor device shown in FIG. 12.

FIGS. 14(A) to 14(C) are step sectional views showing respective manufacturing steps for the semiconductor device shown in FIG. 12.

FIGS. 15(A) to 15(C) are step sectional views showing respective manufacturing steps for the semiconductor device shown in FIG. 12.

FIGS. 16(A) and 16(B) are step sectional views showing respective manufacturing steps for the semiconductor device shown in FIG. 12.

FIG. 17 is a plan view showing a manufacturing step for the semiconductor device which corresponds to FIG. 13(B).

FIG. 18 is a plan view showing a manufacturing step for the semiconductor device which corresponds to FIG. 14(C).

FIG. 19 is a plan view showing first and second silicon regions formed by a manufacturing step for the semiconductor device which corresponds to FIG. 14(C).

FIG. 20 is a plan view showing a manufacturing step for the semiconductor device which corresponds to FIG. 15(A).

FIG. 21 is a plan view showing a manufacturing step for the semiconductor device which corresponds to FIG. 15(B).

FIG. 22 is a plan view showing a manufacturing step for the semiconductor device which corresponds to FIG. 15(C).

FIG. 23 is a plan view showing a manufacturing step for the semiconductor device which corresponds to FIG. 16(A).

FIG. 24(A) is a perspective view showing a liquid crystal panel of an active matrix-type liquid crystal display device provided with the semiconductor device according to the first embodiment, and FIG. 24(B) is a perspective view showing a TFT substrate included in the liquid crystal panel shown in FIG. 24(A).

FIG. 25(A) is a perspective view showing a liquid crystal panel of an active matrix-type liquid crystal display device with a touch panel function which is provided with the semiconductor device according to the second embodiment, and FIG. 25(B) is a circuit diagram showing a configuration of an image display portion included in a TFT substrate of the liquid crystal panel shown in FIG. 25(A).

### MODES FOR CARRYING OUT THE INVENTION

Hereinafter, each of embodiments of the present invention will be described in detail with reference to the drawings, but the present invention is not restricted only to these embodiments.

### 1. First Embodiment

### 1.1 Configuration of Semiconductor Device

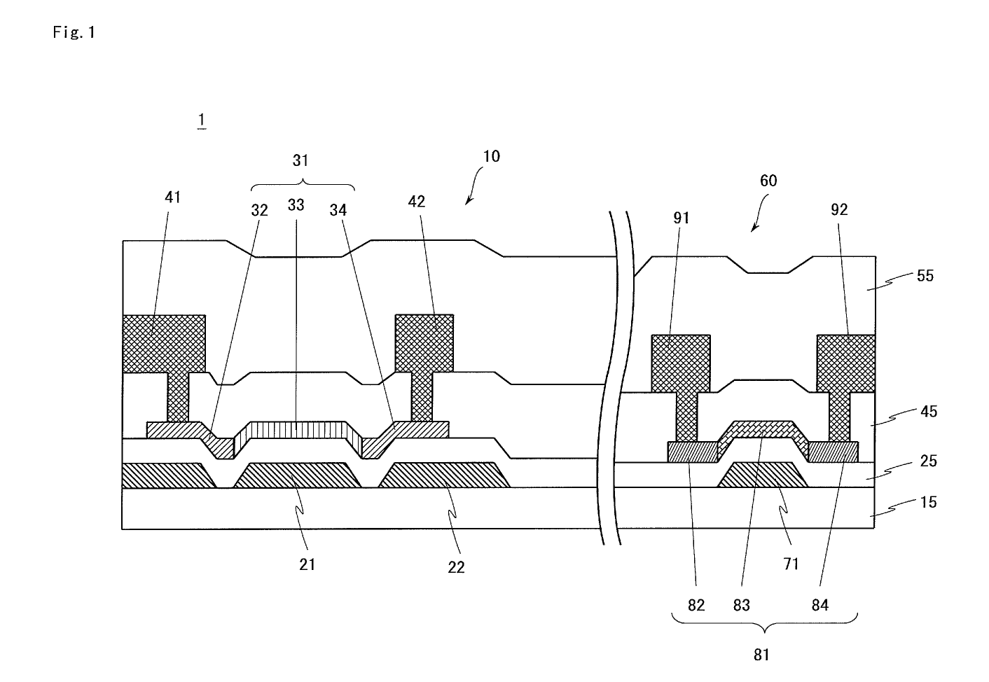

FIG. 1 is a sectional view showing a configuration of a semiconductor device 1 according to a first embodiment of the present invention. As shown in FIG. 1, the semiconductor device 1 includes two kinds of TFTs, a TFT 10 (first thin-film transistor) and a TFT 60 (second thin film transistor), formed on a glass substrate 15 (which may hereinafter be referred to as a “substrate 15”) as a substrate having an insulating surface (which is hereinafter referred to as an “insulating substrate”). Although either of the two kinds of TFTs 10, 60 is a bottom gate type, constituents corresponding thereto respectively have different sizes. The TFT 10 shown on the left side of FIG. 1 is a TFT with each constituent having a large size, and the TFT 60 shown on the right side is a TFT with each constituent having a small size. It is to be noted that, although a description will be given below with both the TFTs 10, 60 being as n-channel TFTs, they may be p-channel TFTs. Further, the glass substrate 15 includes a glass substrate on the surface of which a base coat film made up of an insulating film is formed.

The top of the glass substrate 15 is formed with a gate electrode 21 (first metal pattern or third metal pattern) of the TFT 10, a radiation portion 22 (first metal pattern and fourth metal pattern) surrounding the gate electrode 21, and agate electrode 71 (second metal pattern) of the TFT 60. These gate electrode 21, radiation portion 22, and gate electrode 71 are formed of the same metal. A gate insulating film 25 (insulating film) is formed so as to coat the entire glass substrate 15 including the gate electrode 21, the radiation portion 22, and the gate electrode 71.

The surface of the gate insulating film 25 is formed with an island-like active layer 31 extending laterally over the gate electrode 21 and above the right and left radiation portions 22 as viewed from the top, and an island-like active layer 81 extending laterally over the gate electrode 71 and above the right and left glass substrates 15 as viewed from the top. The active layer 31 of the TFT 10 is configured by crystalline silicon made up of crystal grains with an average grain size of as large as about 3 μm. The right and left hands of the active layer 31 are respectively formed with a source region 32 and a drain region 34 which are doped with a high concentration of n-type impurities. A region sandwiched between the source region 32 and the drain region 34 is a channel region 33, and has a size of, for example, 20 μm×20 μm.

Further, the active layer 81 of the TFT 60 is configured by crystalline silicon made up of crystal grains with an average grain size of as small as about 0.3 μm. The right and left hands of the active layer 81 are respectively formed with a source region 82 and a drain region 84 which are doped with a high concentration of n-type impurities. A region sandwiched between the source region 82 and the drain region 84 is a channel region 83, whose size is smaller than that of the channel region 33 of the TFT 10 and is, for example, 4 μm×4 μm. It is to be noted that in the present specification, the “average grain size” is an average value of sizes of the crystal grains contained in the crystalline semiconductor film such as a crystalline silicon film, and can be measured by means of EBSP (Electron Backscatter Diffraction Patterns), or the like.

An inter-layer insulating film 45 is formed so as to coat the entire glass substrate 15 including the active layers 31, 81. The inter-layer insulating film 45 is opened with respective contact holes that reach source regions 32, 82, respective contact holes that reach the drain regions 34, 84 and respective contact holes (not shown) that reach the gate electrodes 21, 71. The surface of the inter-layer insulating film 45 is formed with source electrodes 41, 91 respectively ohmically connected with the respective source regions 32, 82 via the contact holes. Further, it is formed with drain electrodes 42, 92 respectively ohmically connected with the respective drain regions 34, 84 via the contact holes. Moreover, it is formed with a protective film 55 so as to coat the entire glass substrate 15 including the source electrodes 41, 91 and the drain electrodes 42, 92.

### 1.2 Manufacturing Method for Semiconductor Device

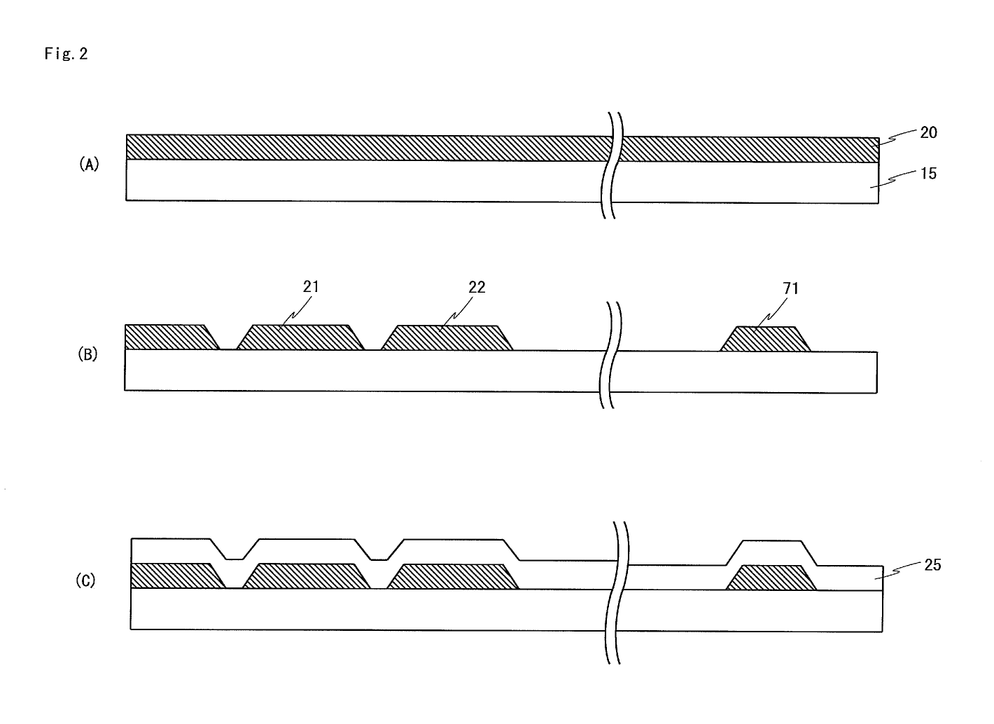

FIGS. 2 to 5 are step sectional views showing respective manufacturing steps for the semiconductor device 1 shown in FIG. 1. As shown in FIG. 2 (A), a molybdenum (Mo) film 20 (metal film) with a film thickness of 50 to 200 nm, for example, 70 nm, is deposited on the glass substrate 15 by means of sputtering. It is to be noted that in place of the molybdenum film 20, a refractory metal film such as a tungsten (W) film, a titanium (Ti) film, or a tantalum (Ta) film, a nitride film of the refractory metal film, or a laminated film formed by laminating those may be deposited by means of sputtering. This can prevent melting of the gate electrodes 21, 71 in a later-mentioned crystallization step.

As shown in FIG. 2(B), in order to pattern the molybdenum film 20, the surface of the molybdenum film 20 is formed with a resist pattern (not shown) by means of photolithography. The molybdenum film 20 is etched with the resist pattern used as a mask, to form the gate electrode 21 and the radiation portion 22 of the TFT 10, and the gate electrode 71 of the TFT 60. Subsequently, the resist pattern is peeled. A width of the gate electrode 21 of the TFT 10 is set, for example, to 20 μm and a width of the gate electrode 71 of the TFT 60 is set, for example, to 4 μm. Further, the radiation portion 22 of the TFT 10 is formed so as to surround the periphery of the gate electrode 21.

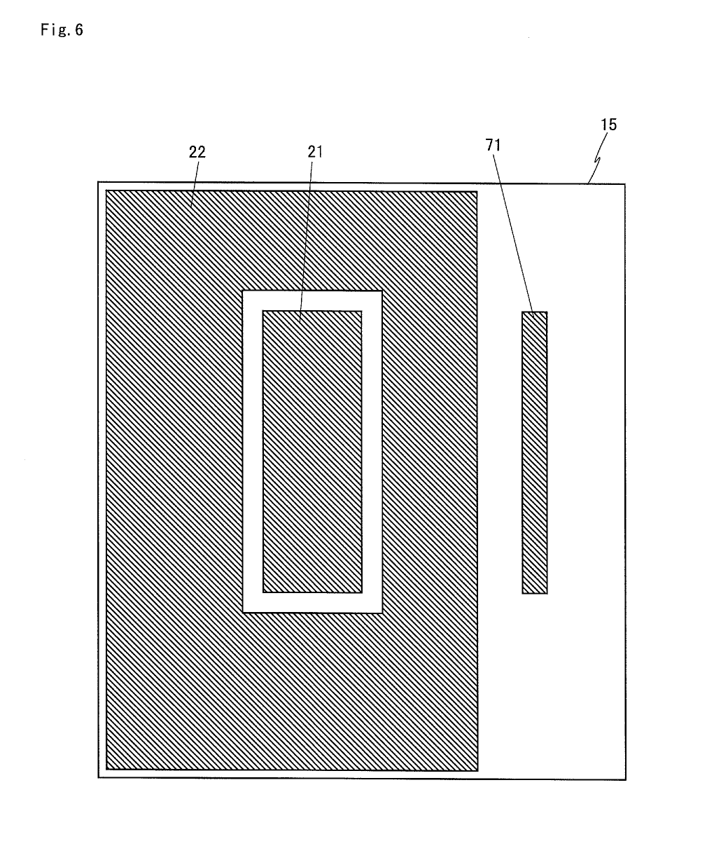

FIG. 6 is a plan view showing a manufacturing step which corresponds to FIG. 2(B). As shown in FIG. 6, the gate electrode 21 and the radiation portion 22 of the TFT 10 and the gate electrode 71 of the TFT 60 are formed on the glass substrate 15. The gate electrode 21 is not only large as compared with the gate electrode 71, but also surrounded by the radiation portion 22 formed at a distance of, for example, just about 2 μm from the end of the periphery of the gate electrode 21.

As shown in FIG. 2(C), the gate insulating film 25 is deposited so as to coat the entire glass substrate 15 including the gate electrodes 21, 71 and the radiation portion 22. The gate insulating film 25 is made up of silicon oxide (SiO₂) with a film thickness of, for example, 100 nm and deposited by means of plasma CVD using TEOS (Tetra Ethoxy Silane) as a source gas, or some other means. It is to be noted that as the gate insulating film 25, a silicon nitride (SiNx) film (x is an arbitrary number), a silicon oxynitride (SiNO) film, or a laminated insulating film formed by laminating those may be deposited in place of the silicon oxide film. Since these films are not denatured in a later-mentioned crystallization step, they function as the insulating films even after the crystallization step.

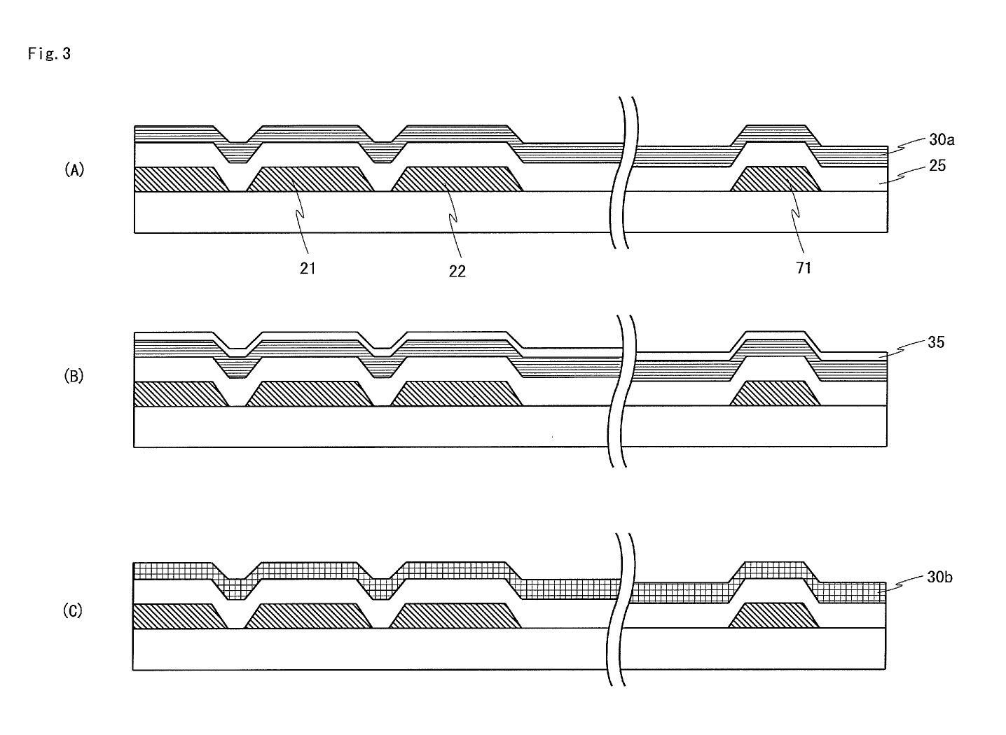

As shown in FIG. 3(A), the surface of the gate insulating film 25 is deposited with an amorphous silicon film 30a (amorphous semiconductor film) with a film thickness of, for example, about 50 nm. The amorphous silicon film 30a is formed by means of low pressure CVD (Low Pressure Chemical Vapor Deposition) using monosilane (SiH₄) gas as a source gas, or some other means.

As shown in FIG. 3(B), a nickel film 35 as a catalyst for promoting crystallization of the amorphous silicon film 30a is vapor-deposited on the surface of the amorphous silicon film 30a by means of, for example, resistive heating. As thus described, vapor-depositing the nickel film 35 on the surface of the amorphous silicon film 30a promotes crystallization of the amorphous silicon film 30a, to allow reduction in time for forming a crystalline silicon film 30b (first crystalline semiconductor film), and also allow an increase in average grain size of the crystalline silicon film 30b.

A favorable range of the concentration of nickel on the surface of the amorphous silicon film 30a is from 1E10 to 1E12 atoms/cm², and it is, for example, 5E10 atoms/cm² in the present embodiment. The reason for favorably limiting the concentration of nickel to the above range will be described. When the concentration of nickel is smaller than 1E10 atoms/cm², the effect of the catalyst is small, leading to non-occurrence of crystallization of the amorphous silicon film or to a very low solid phase epitaxy speed. Further, when the concentration of nickel is larger than 1E12 atoms/cm², the density of the crystal grains due to nickel is high and the grain size of the crystal grain not due to nickel is small inside the crystalline silicon film. A TFT with such a crystalline silicon film serving as an active layer does not show desired electric characteristics.

The concentration in the vicinity of the surface of the amorphous silicon film 30a vapor-deposited with the nickel film 35 is easily measured by means of total reflection X-ray fluorescence analysis. Thereat, in the present specification, the concentration of nickel at a depth of 5 to 10 nm from the surface of the amorphous silicon film 30a is measured by means of total reflection X-ray fluorescence analysis, and the obtained measured value is taken as the concentration of nickel on the surface of the amorphous silicon film 30a.

As shown in FIG. 3(C), the substrate 15 is put into an electric chamber, and subjected to heat treatment in a nitride atmosphere for one hour (first crystallization step). A preferable temperature range for heat treatment is from 500 to 700° C. and in the present embodiment, it is 600° C., for example. By heat treatment by means of the electric chamber, the amorphous silicon film 30a grows by solid phase epitaxy, to become a crystalline silicon film 30b with an average grain size of about 3 μm. Hereat, the range of the preferable temperature at the time of heat treatment is set to 500 to 700° C. for the following reason. When the temperature is lower than 500° C., the epitaxy speed of the crystalline silicon film 30b which grows by solid phase epitaxy is low. Further, when it is higher than 700° C., not only a large crystal grain which has a grain size of not smaller than 3 μm and grows by solid phase epitaxy due to nickel grows, but also a small crystal grain which has a grain size of not larger than 0.2 μm and grows by solid phase epitaxy not due to nickel grows, and hence the crystalline silicon film 30b with a crystal grain boundary having a high density is obtained. When the TFTs 10, 60 are formed by use of a crystalline silicon film 30c obtained by further crystallizing the crystalline silicon film 30b, a decrease in carrier mobility, or the like, occurs and desired electric characteristics cannot be obtained.

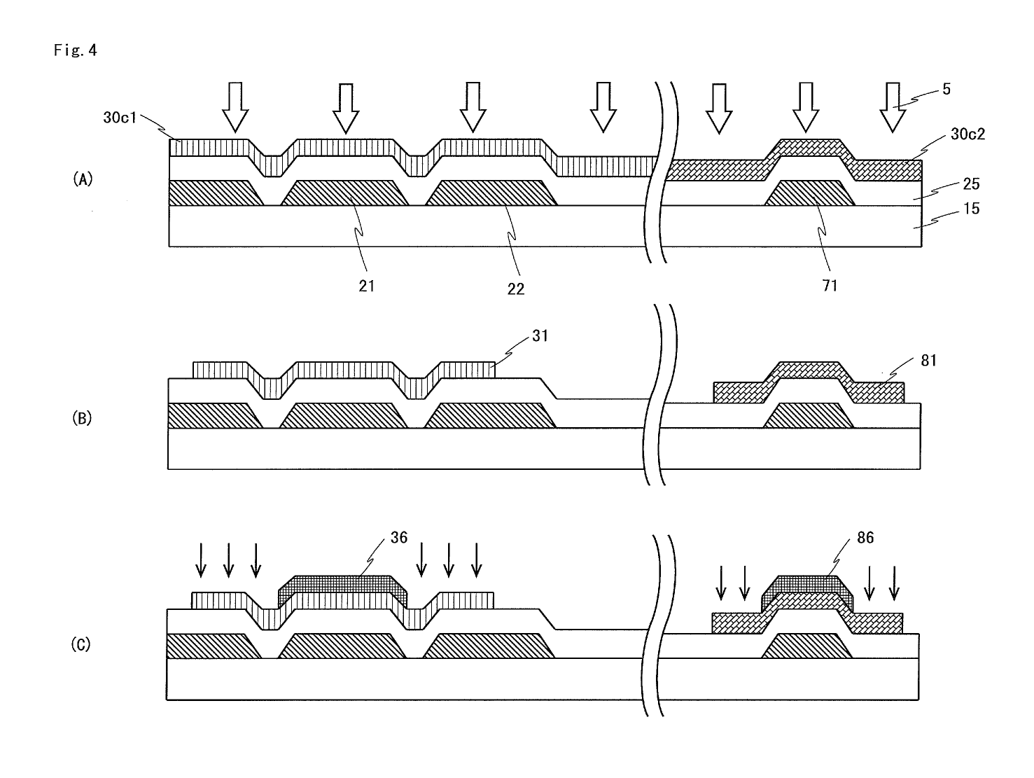

As shown in FIG. 4(A), the surface of the crystalline silicon film 30b is irradiated with a laser beam 5 outputted from a pulse oscillation XeCl excimer laser (second crystallization step), to form crystalline silicon film 30c (second crystalline semiconductor film) including a first silicon region 30c1 (first semiconductor region) and a second silicon region 30c2 (second semiconductor region). The laser beam 5 to be used is a laser beam with a wavelength of 126 to 370 nm, for example, 308 nm, a pulse width of 30 ns, and an energy density of 350 mJ/cm². The wavelength of the laser beam 5 is set to 126 to 370 nm because large energy can be provided in an extremely short time of nanosecond to microsecond order, and light in an ultraviolet region is apt to be absorbed in silicon.

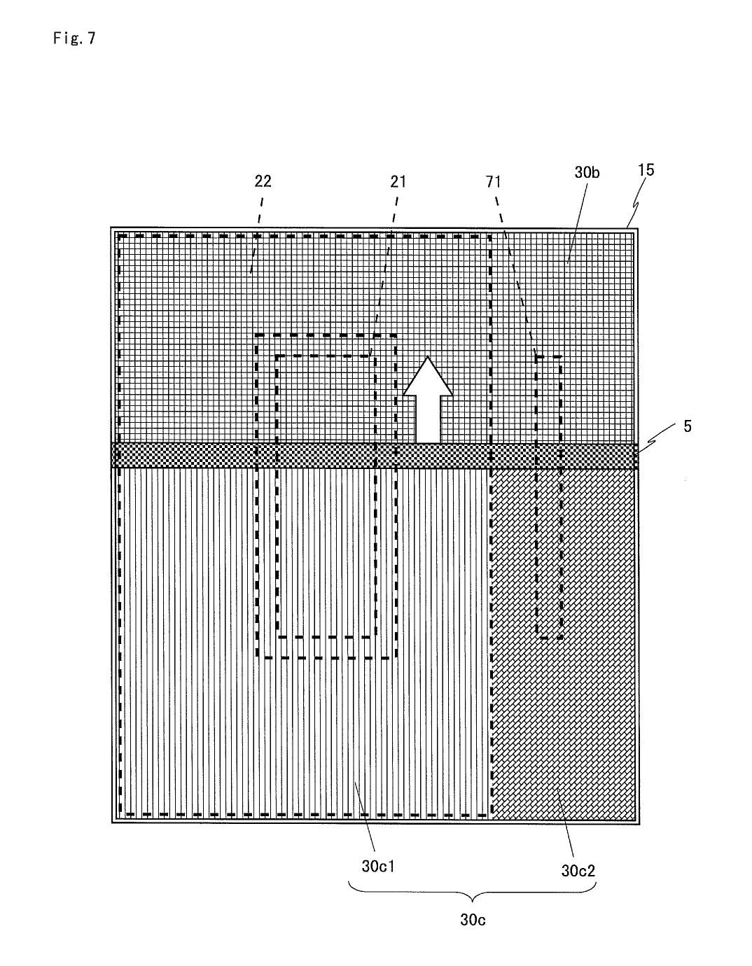

FIG. 7 is a plan view showing a manufacturing step which corresponds to FIG. 4(A). As shown in FIG. 7, on the surface of the crystalline silicon film 30b, the laser beam 5 formed in a rectangular shape of 125 mm×0.4 mm is scanned in its short-axial direction (direction of an arrow shown in FIG. 7) with a step width of 20 μm/pulse along the surface of the crystalline silicon film 30b. This leads to crystallization of the crystalline silicon film 30b, and simultaneous formation of the first silicon region 30c1 and the second silicon region 30c2.

Specifically, by being irradiated with the laser beam 5, the crystalline silicon film 30b begins to be melted from its surface, and the crystalline silicon film 30b above the gate electrode 21 and the radiation portion 22 becomes the first silicon region 30c1 while the crystalline silicon film 30b above the gate electrode 71 becomes the second silicon region 30c2. At this time, in the crystalline silicon film 30b above the gate electrode 21 and the radiation portion 22, even when its surface is melted, the crystalline silicon film 30b located at a distance of just 5 nm upward from an interface with the gate insulating film 25 is not melted. For this reason, the average grain size of the first silicon region 30c1 is almost the same as, and not changed from, the 3-μm average grain size of the crystalline silicon film 30b.

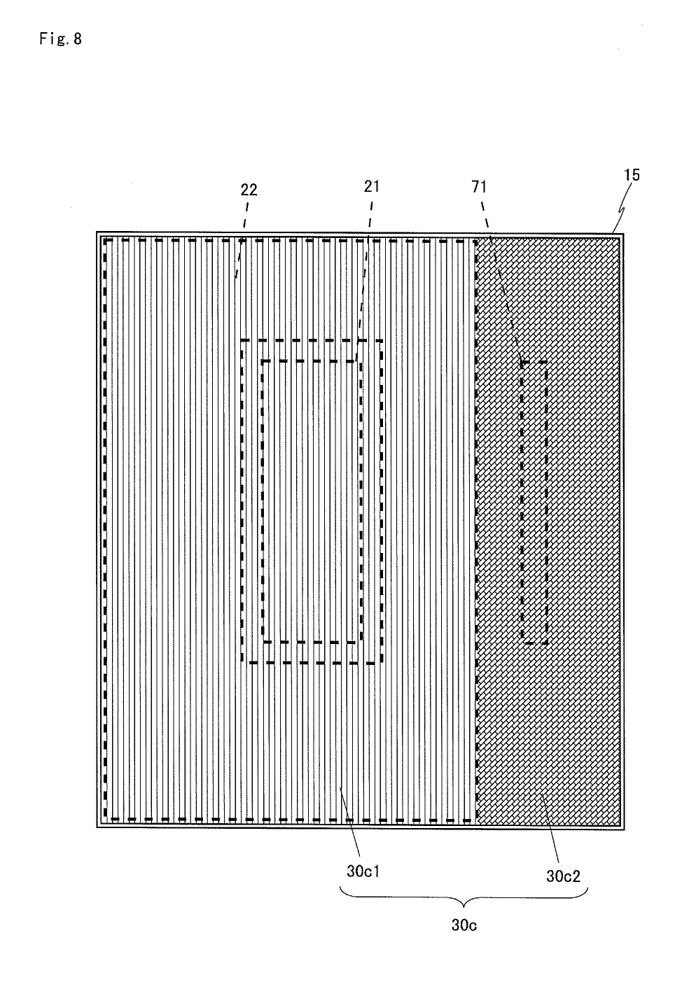

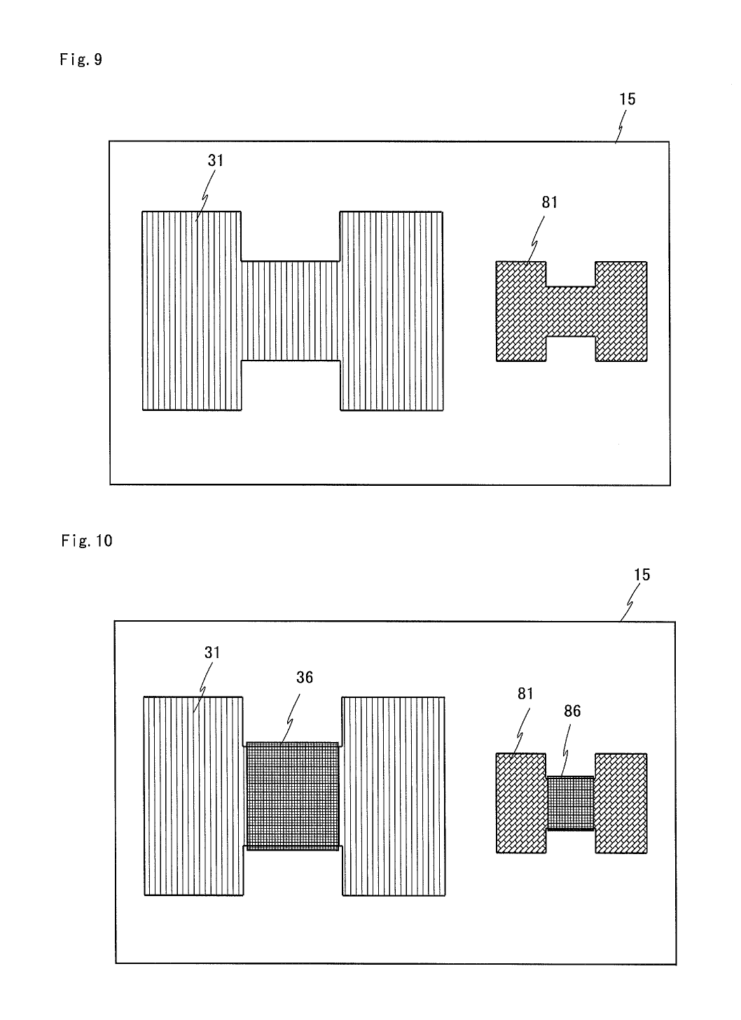

Meanwhile, the crystalline silicon film 30b above the gate electrode 71 is completely melted and then solidified, to become the second silicon region 30c2. Thereby, the second silicon region 30c2 has an average grain size of 0.3 μm, which is quite small as compared with the 3-μm average grain size of the crystalline silicon film 30b. As thus described, irradiating the crystalline silicon film 30b with the laser beam 5 can simultaneously form the first silicon region 30c1 having a large average grain size and the second silicon region 30c2 having a smaller average grain size than that of the first silicon region 30c1. FIG. 8 is a plan view showing first and second silicon regions 30c1, 30c2 formed by a manufacturing step which corresponds to FIG. 4(A). As shown in FIG. 8, the first silicon region 30c1 with a large average grain size is formed above the gate electrode 21 and the radiation portion 22, and the second silicon region 30c2 with a small average grain size is formed above the gate electrode 71.

It is to be noted that scanning the laser beam 5 with a step width of 20 μm/pulse means moving the laser beam 5 by 20 μm at each one-pulse irradiation. The step width may be a width with which the crystalline silicon film 30b can be crystallized without a break, and can be appropriately set. Further, since the shape of the laser beam 5 is a rectangle with a very large aspect ratio, it can be practically referred to as a linear shape. Step-scanning such a linear laser beam 5 can crystallize the crystalline silicon film 30b with a large area in a short time, to allow simultaneous formation of the first silicon region 30c1 and the second silicon region 30c2. Further, the laser beam 5 usable in the present embodiment is not limited to the foregoing laser beam, but can be any laser beam so long as it completely melts the crystalline silicon film 30b above the gate electrode 71, and does not melt the crystalline silicon film 30b located at a distance of just 5 nm upward from the interface between the gate electrode 21/radiation portion 22 and the gate insulating film 25.

The average grain size of the first silicon region 30c1 has hardly changed from the average grain size of the crystalline silicon film 30b by the foregoing crystallization for the following reason. The radiation portion 22 is formed on the periphery of the gate electrode 21 so as to have as large an area as possible in the range of not becoming an obstacle at the time of forming a wiring layer on the glass substrate 15. As shown in FIG. 7, the radiation portion 22 with a large area and a large heat capacity is expanded below the crystalline silicon film 30b. Since a length of the radiation portion 22 is sufficiently larger than a length in the short-axial direction of the laser beam 5 used in the crystallization step, even when the laser beam 5 is step-scanned in its short-axial direction to provide heat energy to the crystalline silicon film 30b, much of the heat energy escapes to the radiation portion 22 via the gate insulating film 25. For this reason, a temperature of the crystalline silicon film 30b above the gate electrode 21 and the radiation portion 22 does not sufficiently increase, and the crystalline silicon film 30b cannot be completely melted. Accordingly, the average grain size of the first silicon region 30c1 remains almost the same as the average grain size of the crystalline silicon film 30b, but its crystallinity improves. That is, since the lengths of the gate electrode 21 and the radiation portion 22 are sufficiently larger than the length in the short-axial direction of the laser beam 5, the first silicon region 30c1 effectively obtains the same result as in the case of being irradiated with a laser beam with a small energy density. As opposed to this, since the gate electrode 71 has a small area and a small heat capacity, even when part of the heat energy given to the crystalline silicon film 30b above the gate electrode 71 escapes to the gate electrode 71, a large part of the heat energy is used for crystallization of the crystalline silicon film 30b. Since this leads to sufficient heating and complete melting of the crystalline silicon film 30b, the average grain size of the second silicon region 30c2 is smaller than the average grain size of the first silicon region 30c1.

As shown in FIG. 4(B), a resist pattern (not shown) is formed on the surfaces of the first silicon region 30c1 and the second silicon region 30c2 by means of a photography technique, and the resist pattern is used as a mask, to etch the first silicon region 30c1 and the second silicon region 30c2. Subsequently, the resist pattern is peeled. This results in formation of the island-like active layer 31 above the gate electrode 21 and the radiation portion 22 and the island-like active layer 81 above the gate electrode 71. FIG. 9 is a plan view showing a manufacturing step which corresponds to FIG. 4(B). As shown in FIG. 9, patterning the first silicon region 30c1 and the second silicon region 30c2 can form the active layer 31 and the active layer 81 each having an H shape.

As shown in FIG. 4(C), resist patterns 36, 86 are respectively formed so as to coat regions to be channel regions of the active layers 31, 81, and with the resist patterns 36, 86 used as masks, phosphorus (P) ions as n-type impurity ions are respectively ion-implanted into or ion-doped to the active layers 31, 81. FIG. 10 is a plan view showing a manufacturing step which corresponds to FIG. 4(C). As shown in FIG. 10, the resist patterns 36, 86 are respectively formed at the central portions of the active layers 31, 81.

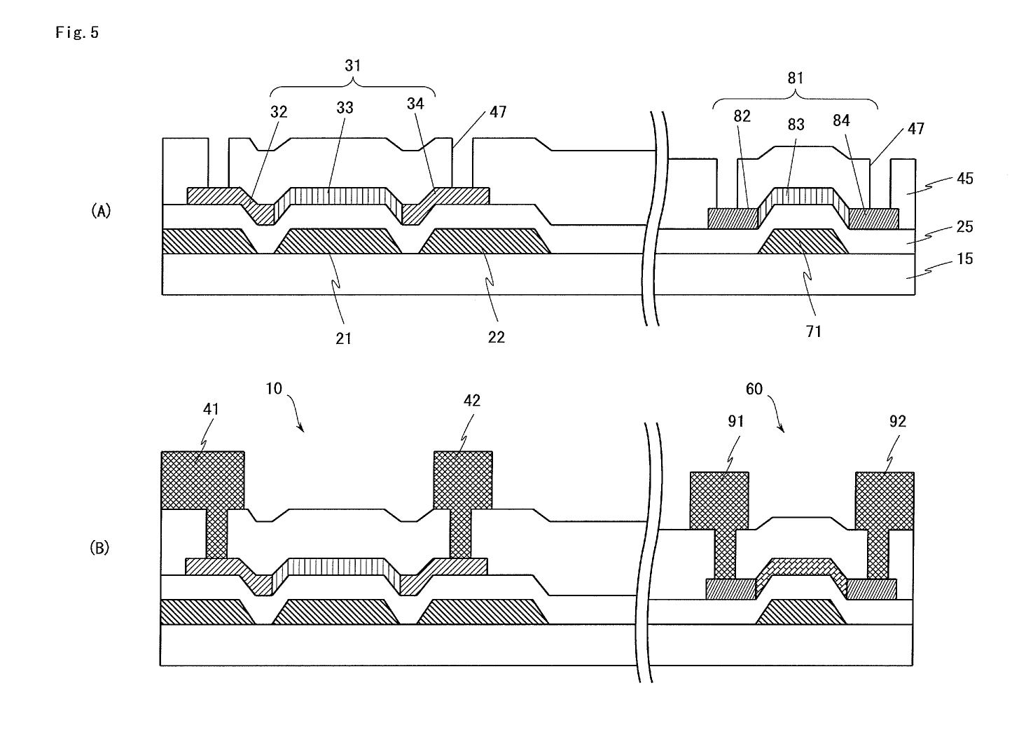

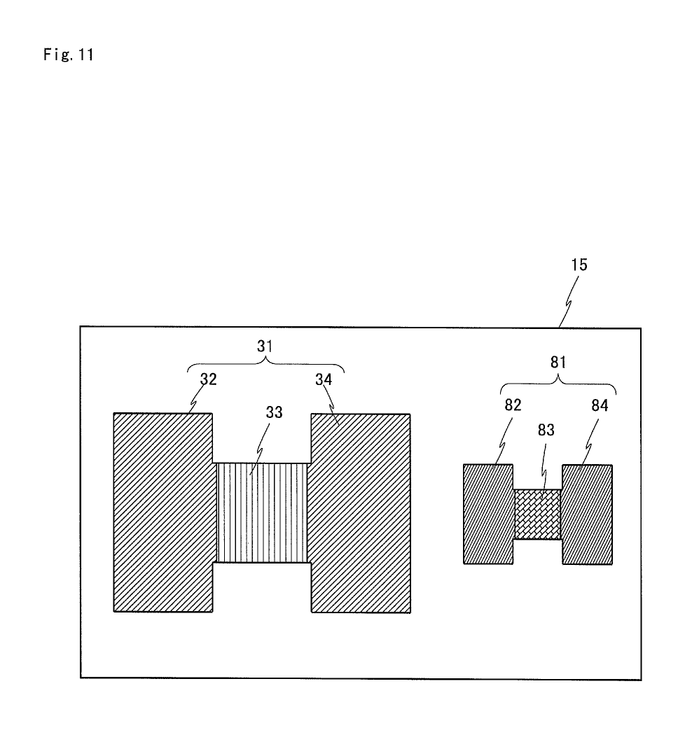

After peeling of the resist patterns 36, 86, the substrate 15 is annealed in the electric chamber, to activate the phosphorus ions. This results in that, as shown in FIG. 5(A), the source region 32 and the drain region 34 are formed in the active layer 31, and the channel region 33 is formed in a region sandwiched between the source region 32 and the drain region 34. A source region 82 and the drain region 84 are formed in the active layer 81, and the channel region 83 is formed in a region sandwiched between the source region 82 and the drain region 84. A size of the channel region 33 formed in the active layer 31 is, for example, 20 μm×20 μm and a size of the channel region 83 formed in the active layer 81 is, for example, 4 μm×4 μm. FIG. 11 is a plan view showing a manufacturing step which corresponds to FIG. 5(A). As shown in FIG. 11, the source region 32, the channel region 33, and the drain region 34 are formed in the active layer 31, and the source region 82, the channel region 83, and the drain region 84 are formed in the active layer 81.

Further, the inter-layer insulating film 45 is deposited so as to coat the entire glass substrate 15 including the active layers 31, 81. The inter-layer insulating film 45 is, for example, made up of an oxide silicon film having a film thickness of about 300 nm, and deposited by means of atmospheric pressure CVD (Atmospheric Pressure Chemical Vapor Deposition) using TEOS as a source gas, or some other means. Next, the top of the inter-layer insulating film 45 is formed with a resist pattern (not shown) by means of photolithography, and then opened with contact holes 47 that reach the source regions 32, 82 and the drain regions 34, 84, with the resist pattern used as a mask. Subsequently, the resist pattern is peeled. At this time, contact holes (not shown) that reach the gate electrodes 21, 71 are simultaneously opened. It is to be noted that as the inter-layer insulating film 45, a silicon nitride film, a silicon oxynitride film, or a laminated insulating film formed by laminating those may be deposited in place of the silicon oxide film.

As shown in FIG. 5(B), an aluminum (Al) film (not shown) is deposited on the entire surface of the glass substrate 15 including the inside of the contact hole 47 by means of sputtering. The surface of the aluminum film is formed with a resist pattern (not shown) by means of photolithography, and the aluminum film is etched with the resist pattern used as a mask. Subsequently, the resist pattern is peeled, and the substrate 15 is heat-treated. Therefore, a source electrode 41 ohmically connected with the source region 32 and a drain electrode 42 ohmically connected with the drain region 34 are formed via the contact holes 47. Similarly, a source electrode 91 and a drain electrode 92 are also formed. This results in formation of the TFT 10 including the gate electrode 21 and the active layer 31, and the TFT 60 including the gate electrode 71 and the active layer 81. A protective film (not shown) made up of a silicon nitride film is deposited by means of plasma CVD so as to coat the entire glass substrate 15 including the TFT 10 and the TFT 60. In such a manner, the semiconductor device 1 including the TFT 10 and the TFT 60 is manufactured.

### 1.3 Electric Characteristics of Semiconductor Device

As for the TFT 10 included in the semiconductor device 1 manufactured by the foregoing manufacturing method, when its carrier mobility was measured, a value as high as 350 cm²/V·s was obtained. Further, as for the TFT 60, when its carrier mobility was measured, a value of 180 cm²/V·s was obtained which was low as compared with that of the TFT 10. However, when 50 TFTs 60 were produced and threshold voltages thereof were measured, a variation in threshold voltage was as small as 0.05 V. On the other hand, when a TFT with each constituent having the same size as that of the TFT 60 was produced in the first silicon region 30c1 formed with the active layer 31 of the TFT 10 and its carrier mobility was measured, a value as high as 370 cm²/V·s was obtained. However, when 50 of the above TFTs were produced and threshold voltages thereof were measured, a variation in threshold voltage of 0.15 V was obtained which was large as compared with that in the case of the TFTs 60 produced in the second silicon region 30c2. As thus described, the carrier mobility could be made high in the TFT 10 formed in the first silicon region 30c1, and the variation in threshold voltage could be made small in the TFT 60 formed in the second silicon region 30c2.

### 1.4 Effect

According to the manufacturing method of the present embodiment, not only the gate electrode 21 and the gate electrode 71 are previously formed but also the radiation portion 22 is previously formed on the periphery of the gate electrode 21, and on the crystalline silicon film 30b formed above those films, the crystallization step is performed twice in total, including one-time laser annealing, thereby to allow formation of the crystalline silicon film 30c including the first silicon region 30c1 and the second silicon region 30c2 with different average grain sizes. This can simplify the manufacturing method for the semiconductor device 1 by use of the first silicon region 30c1 and the second silicon region 30c2. Further, the first silicon region 30c1 is formed so as to be located above the gate electrode 21 and the radiation portion 22, and the second silicon region 30c2 is formed so as to be located above the gate electrode 71. As thus described, only deciding whether to provide the radiation portion 22 can lead to selection of optimum silicon regions respectively for the TFTs 10, 60 out of the first and second silicon regions 30c1, 30c2.

Further, since the average grain sizes are different between the first silicon region 30c1 and the second silicon region 30c2 of the crystalline silicon 30c formed by the manufacturing method of the present embodiment, electric characteristics, such as carrier mobilities, are also different therebetween. For example, forming the TFT 10 with the first silicon region 30c1 serving as the active layer can improve gate voltage-on current characteristics. Further, forming the TFT 60 with the second silicon region 30c2 serving as the active layer can reduce the variation in threshold voltage.

### 2. Second Embodiment

### 2.1 Configuration of Semiconductor Device

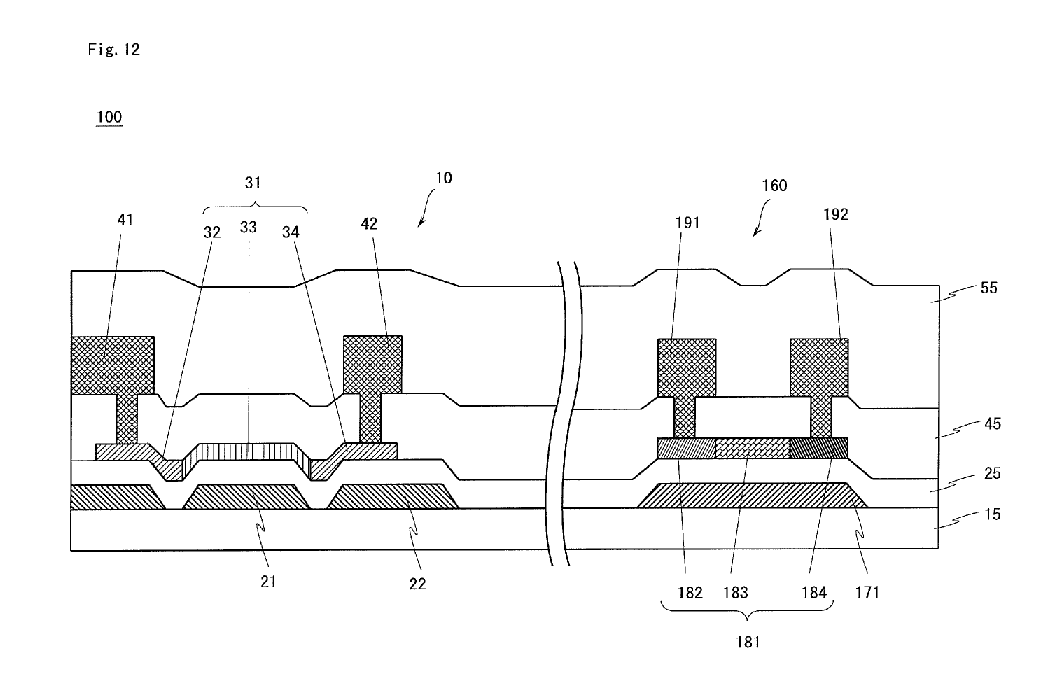

FIG. 12 is a sectional view showing a configuration of a semiconductor device 100 according to a second embodiment of the present invention. As shown in FIG. 12, the semiconductor device 100 includes the TFT 10 (first thin film transistor) and a photodiode 160 which are formed on the glass substrate 15 as an insulating substrate. The TFT 10 shown on the left side of FIG. 12 is a TFT with the same structure as that of the TFT 10 of the first embodiment. The photodiode 160 shown on the right side is a photodiode with a PIN structure. Since the TFT 10 of the present embodiment has the same structure as that of the TFT 10 of the first embodiment, the same reference numeral is provided to each constituent, and a description will be given with a focus on the structure of the photodiode 160.

The top of the glass substrate 15 is formed with the gate electrode 21 (first metal pattern or third metal pattern) of the TFT 10, the radiation portion 22 (first metal pattern and fourth metal pattern) surrounding the gate electrode 21, and a light-blocking film 171 (second metal pattern) of the photodiode 160. These gate electrode 21, radiation portion 22, and light-blocking film 171 are formed of the same metal. The insulating film 25 is formed so as to coat the entire glass substrate 15 including the gate electrode 21, the radiation portion 22, and the light-blocking film 171. The insulating film 25 serves as a gate insulating film of the TFT 10, and also serves as an insulating film to electrically separate the light-blocking film 171 and a later-mentioned active layer 181 in the photodiode 160. Thereat, in the present embodiment, the insulating film 25 is referred to as a gate insulating film 25 for the sake of convenience.

The surface of the gate insulating film 25 is formed with the island-like active layer 31 extending laterally over the gate electrode 21 and above the right and left radiation portion 22 as viewed from the top, and the island-like active layer 181 located above the light-blocking film 171 in plan view. The active layer 31 of the TFT 10 is configured by crystalline silicon made up of crystal grains with an average grain size of as large as about 3 μm. The right and left hands of the active layer 31 are respectively formed with the source region 32 and a drain region 34 which are doped with a high concentration of n-type impurities, and the channel region 33 sandwiched therebetween and having a size of 20 μm×20 μm. The active layer 181 of the photodiode 160 is configured by crystalline silicon made up of crystal grains with an average grain size of as small as about 0.3 μm. The left hand of the active layer 181 is formed with a cathode region 182 doped with a high concentration of n-type impurities, the right hand thereof is formed with an anode region 184 doped with a high concentration of p-type impurities, and a region sandwiched between the cathode region 182 and the anode region 184 is formed with an intrinsic region 183 not containing impurities.

The inter-layer insulating film 45 is formed so as to coat the entire glass substrate 15 including the active layers 31, 181. The inter-layer insulating film 45 is opened respectively with contact holes that reach the source region 32 and the drain region 34 of the TFT 10, a contact hole (not shown) that reaches the gate electrode 21, and contact holes that reach the cathode region 182 and the anode region 184 of the photodiode 160. The surface of the inter-layer insulating film 45 is formed with the source electrode 41 and the drain electrode 42 which are respectively ohmically connected with the source region 32 and the drain region 34 via contact holes, and a cathode electrode 191 and an anode electrode 192 which are respectively ohmically connected with the cathode region 182 and the anode region 184 via the contact holes. Moreover, it is formed with the protective film 55 so as to coat the entire glass substrate 15 including the source electrode 41, the drain electrode 42, the cathode electrode 191, and the anode electrode 192.

### 2.2 Manufacturing Method for Semiconductor Device

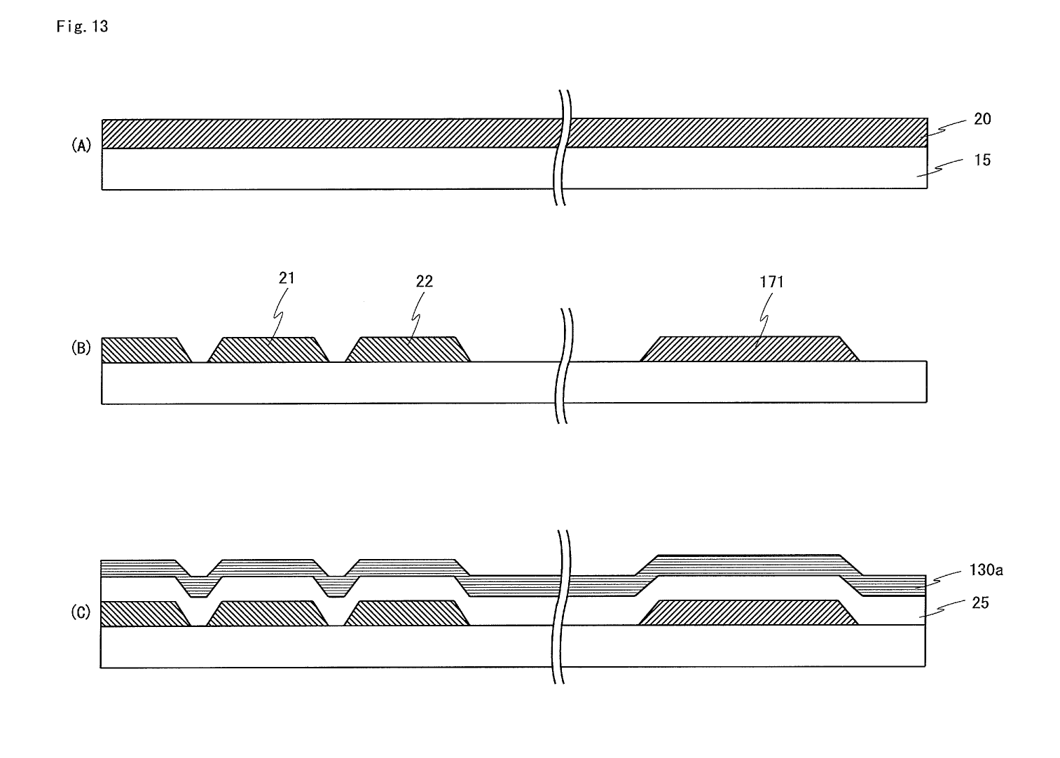

FIGS. 13 to 16 are step sectional views showing respective manufacturing steps for the semiconductor device 100 shown in FIG. 12. In the following description, the same manufacturing step as the manufacturing step for the semiconductor device 1 according to the first embodiment will be briefly described. As shown in FIG. 13(A), a molybdenum film 20 (metal film) with a film thickness of, for example, 70 nm is deposited on the glass substrate 15 by means of sputtering.

As shown in FIG. 13(B), the surface of the molybdenum film 20 is formed with a resist pattern (not shown) by means of photolithography, and the molybdenum film 20 is etched with the resist pattern used as a mask. In such a manner, the gate electrode 21 and the radiation portion 22 of the TFT 10 and the light-blocking film 171 of the photodiode 160 are formed. In this case, a width of the gate electrode 21 of the TFT 10 is set, for example, to 20 μm and a width of the light-blocking film 171 of the photodiode 160 is set, for example, to 5 μm.

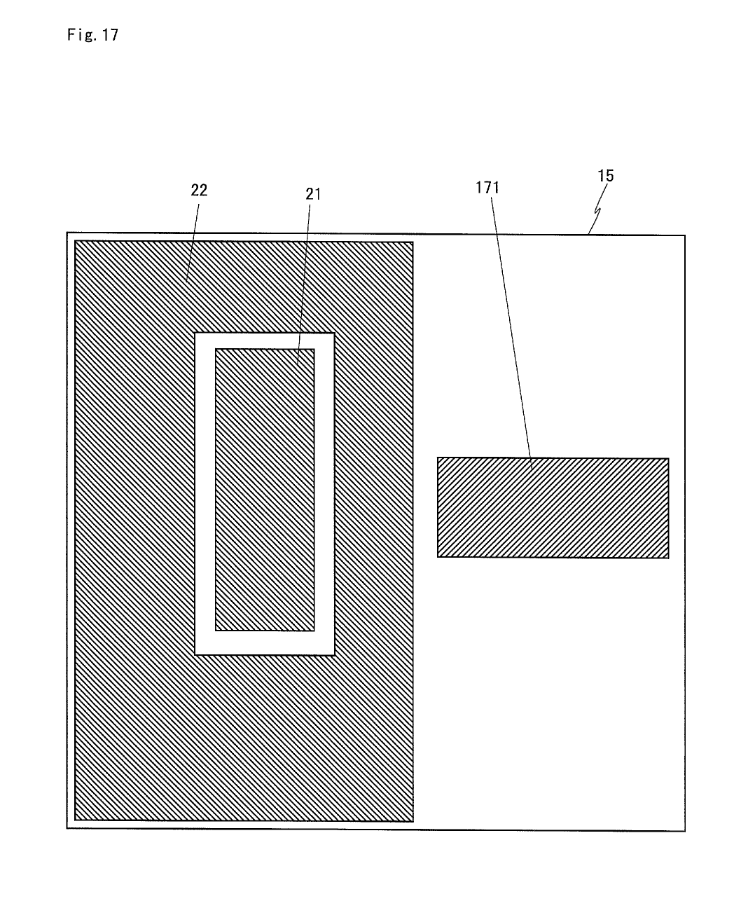

FIG. 17 is a plan view showing a manufacturing step which corresponds to FIG. 13(B). As shown in FIG. 17, the gate electrode 21 and the radiation portion 22 of the TFT 10 and the light-blocking film 171 of the photodiode 160 are formed on the glass substrate 15. The gate electrode 21 is not only large as compared with the light-blocking film 171 of the photodiode 160, but also its periphery is surrounded by the radiation portion 22 formed at a distance of, for example, just about 2 μm from the end of the periphery of the gate electrode 21.

As shown in FIG. 13(C), the gate insulating film 25 made up of silicon oxide is deposited so as to coat the entire glass substrate 15 including the gate electrode 21, the radiation portion 22, and the light-blocking film 171. The gate insulating film 25 has a film thickness of, for example, 100 nm and deposited by means of plasma CVD using TEOS as a source gas, or some other means. Further, the surface of the gate insulating film 25 is f deposited with an amorphous silicon film 130a (amorphous semiconductor film). The amorphous silicon film 130a has a film thickness of, for example, 50 nm and deposited by means of low pressure CVD using monosilane gas as a source gas, or some other means.

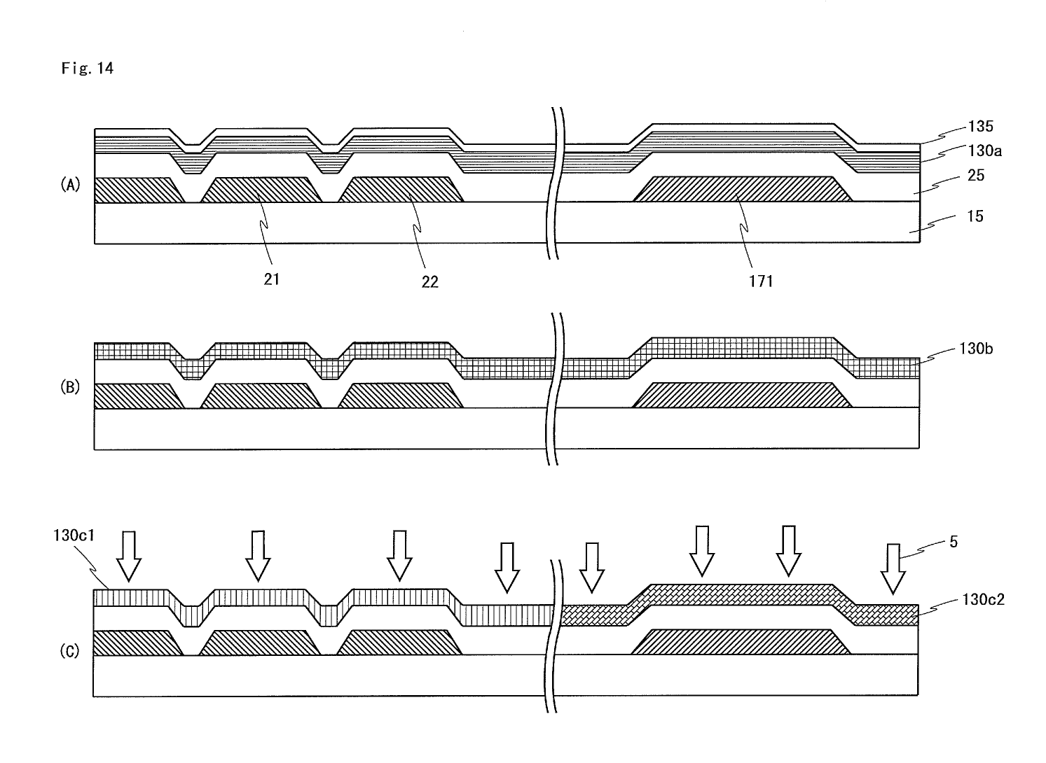

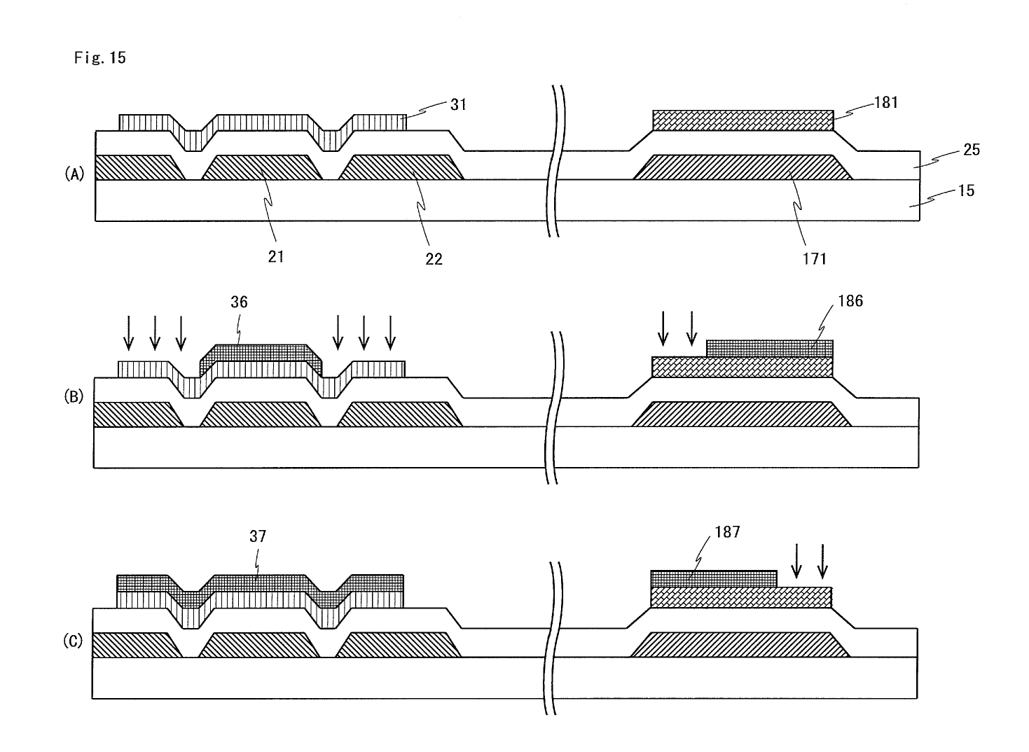

As shown in FIG. 14(A), a nickel film 135 is vapor-deposited on the surface of the amorphous silicon film 130a by means of resistive heating or the like. The concentration of nickel on the surface of the amorphous silicon film 130a is, for example, 5E12 atoms/cm², as in the case of the first embodiment.

As shown in FIG. 14(B), the substrate 15 is put into the electric chamber, and subjected to heat treatment in a nitride atmosphere at, for example, 600° C. for one hour (first crystallization step). By heat treatment by means of the electric chamber, the amorphous silicon film 130a grows by solid phase epitaxy, to become a crystalline silicon film 130b (first crystalline semiconductor film) with an average grain size of about 3 μm.

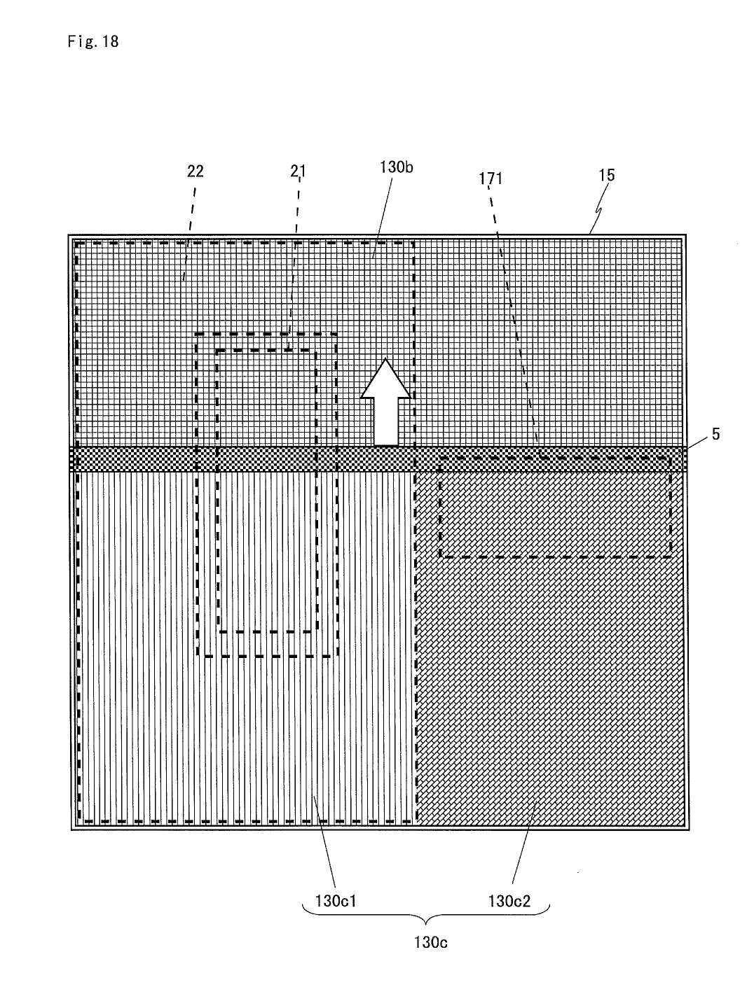

As shown in FIG. 14(C), the surface of the crystalline silicon film 130b is irradiated with the laser beam 5 outputted from a pulse oscillation excimer laser (second crystallization step), to form a crystalline silicon film 130c (second crystalline semiconductor film) including a first silicon region 130c1 (first semiconductor region) and a second silicon region 130c2 (second semiconductor region). FIG. 18 is a plan view showing a manufacturing step which corresponds to FIG. 14(C). As shown in FIG. 18, the laser beam 5 formed in a rectangular shape of 125 mm×0.4 mm is scanned in its short-axial direction (direction of an arrow shown in FIG. 18) with a step width of 20 μm/pulse along the surface of the crystalline silicon film 130b. This leads to crystallization of the crystalline silicon film 130b, and simultaneous formation of the first silicon region 130c1 and the second silicon region 130c2.

Specifically, by being irradiated with the laser beam 5, the crystalline silicon film 130b begins to be melted from its surface, and the crystalline silicon film 130b above the gate electrode 21 and the radiation portion 22 becomes the first silicon region 130c1 while the crystalline silicon film 130b above the light-blocking film 171 becomes the second silicon region 130c2. As in the case of the first embodiment, the average grain size of the first silicon region 130c1 is almost the same as, and not changed from, the 3-μm average grain size of the crystalline silicon film 130b.

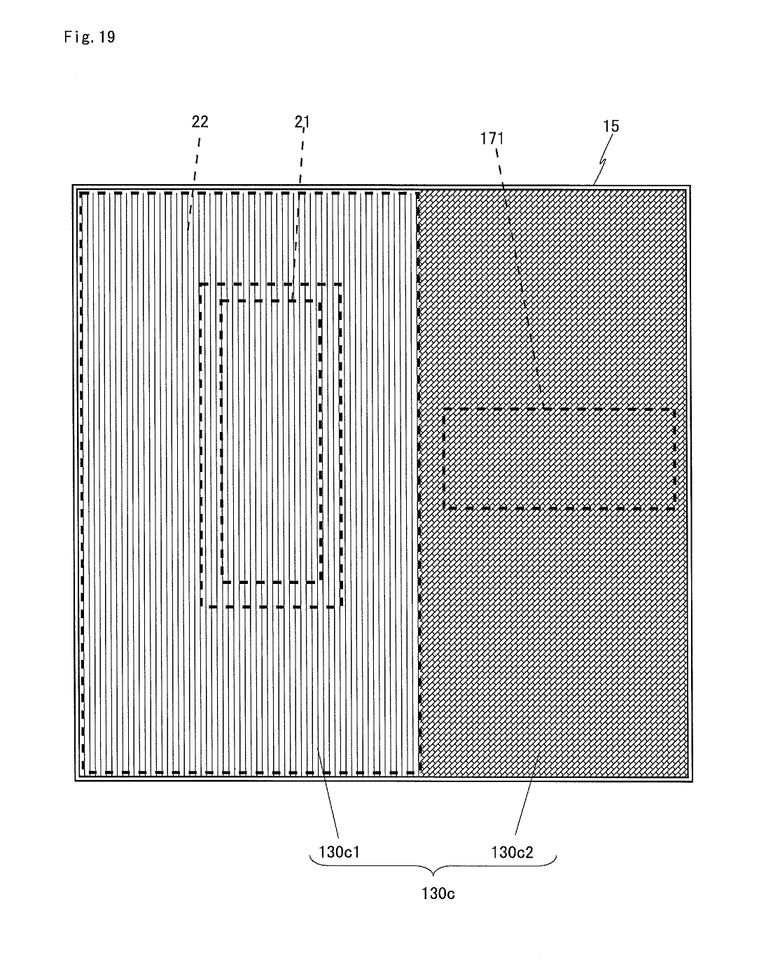

Meanwhile, the crystalline silicon film 130b above the light-blocking film 171 is completely melted and then solidified, to become the second silicon region 130c2. For this reason, as in the case of the first embodiment, the second silicon region 130c2 has an average grain size of 0.3 μm, which is quite small as compared with the 3-μm average grain size of the crystalline silicon film 130b. As thus described, irradiating the crystalline silicon film 130b with the laser beam 5 can simultaneously form the first silicon region 130c1 having a large average grain size and the second silicon region 130c2 having a smaller average grain size than that of the first silicon region 130c1. The reason for forming the first and second silicon regions 130c1, 130c2 with different average grain sizes by the above method is the same as in the case of the first embodiment, and its description is thus omitted. FIG. 19 is a plan view showing the first and second silicon regions 130c1, 130c2 formed by a manufacturing step which corresponds to FIG. 14 (C) . As shown in FIG. 19, the first silicon region 130c1 is formed above the gate electrode 21 and the radiation portion 22, and the second silicon region 130c2 is formed above the light-blocking film 171.

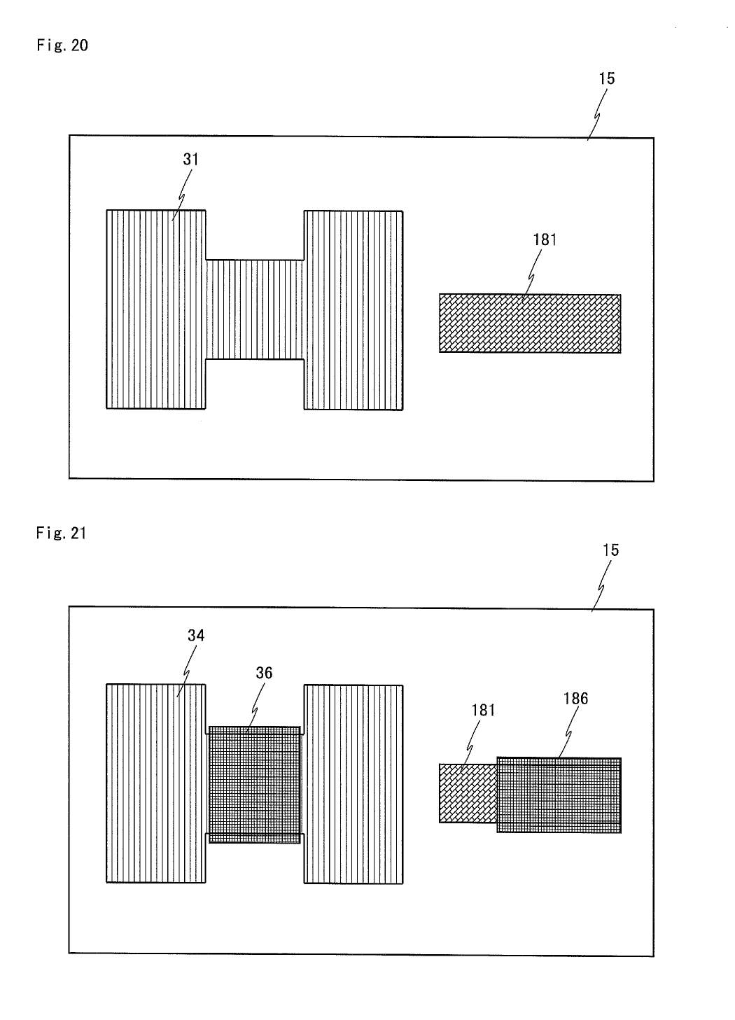

As shown in FIG. 15(A), the first silicon region 130c1 and the second silicon region 130c2 are patterned by means of photolithography, and the island-like active layers 31 are formed above the gate electrode 21 and the radiation portion 22 and the island-like active layer 181 is formed above the light-blocking film 171. A size of the region to be the channel region of the active layer 31 is, for example, 20 μm×20 μm. A size of each of regions to be the cathode region and the anode region of the active layer 181 is, for example, 10 μm×10 μm and a size of a region to be the intrinsic region is, for example, 5 μm×10 μm. FIG. 20 is a plan view showing a manufacturing step which corresponds to FIG. 15(A). As shown in FIG. 20, patterning the first silicon region 130c1 and the second silicon region 130c2 can form the active layer 31 having an H shape and the active layer 181 having a rectangular shape.

As shown in FIG. 15(B), resist patterns 36, 186 are respectively formed so as to coat the region to be the channel region of the TFT 10 and the regions to be the anode region and the intrinsic region of the photodiode 160. With the resist patterns 36, 186 used as masks, phosphorus ions are ion-implanted or ion-doped. FIG. 21 is a plan view showing a manufacturing step which corresponds to FIG. 15(B). As shown in FIG. 21, the resist pattern 36 that coats the central portion of the active layer 31 and the resist pattern 186 that coats an area from the central portion to the right end of the active layer 181 are formed.

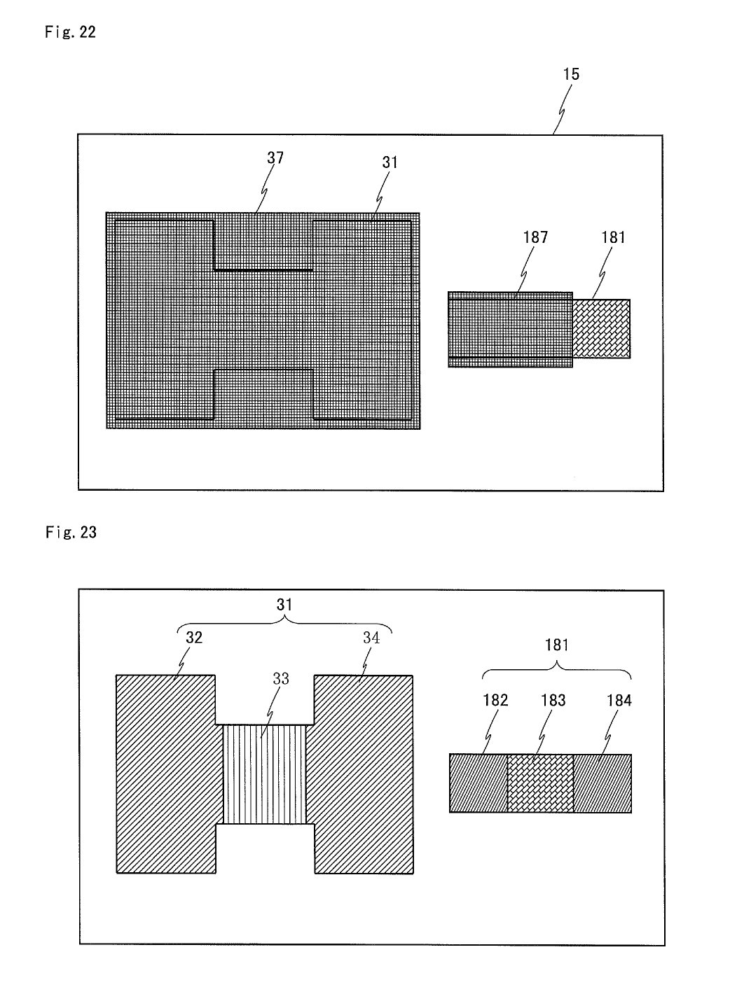

As shown in FIG. 15(C), after the resist patterns 36, 186 have been peeled, resist patterns 37, 187 are respectively formed so as to coat the entire active layer 31 of the TFT 10 and the regions to be the cathode region and the intrinsic region of the photodiode 160. With the resist patterns 37, 187 used as masks, boron (B) ions as p-type phosphorus impurity ions are ion-implanted or ion-doped. FIG. 22 is a plan view showing a manufacturing step which corresponds to FIG. 15(C). As shown in FIG. 22, the resist pattern 37 that coats the entire active layer 31 and the resist pattern 187 that coats an area from the central portion to the left end of the active layer 181 are formed.

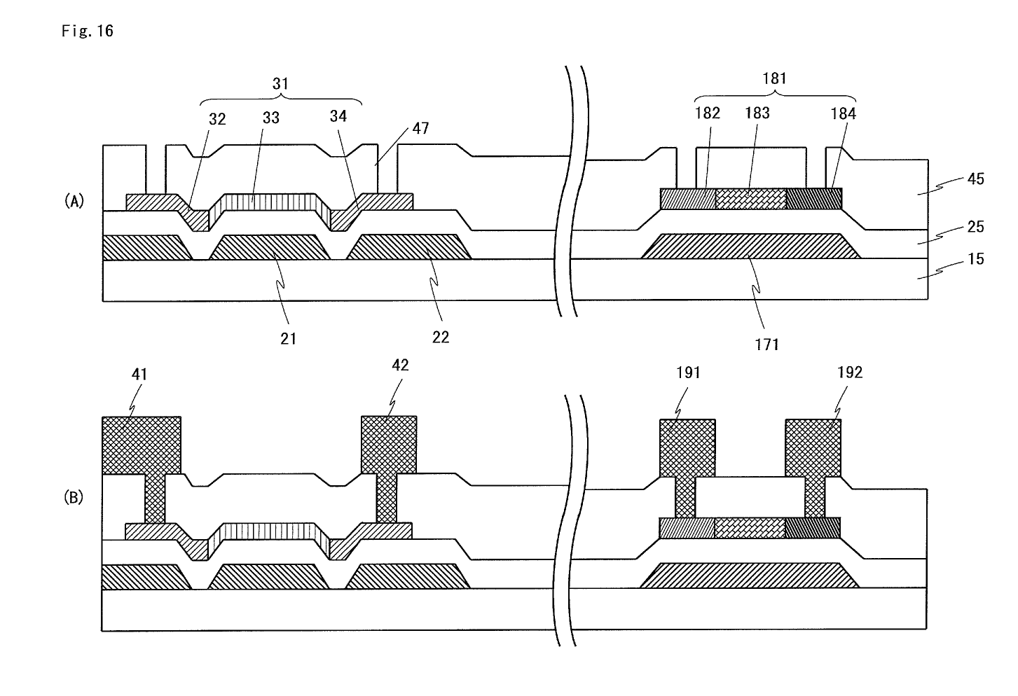

After removal of the resist patterns 37, 187, the substrate 15 is annealed in the electric chamber, to activate the phosphorus ions and the boron ions. This results in that, as shown in FIG. 16(A), the source region 32 and the drain region 34 are formed in the active layer 31, and the cathode region 182 and the anode region 184 are formed in the active layer 181. Further, a region sandwiched between the source region 32 and the drain region 34 of the active layer 31 becomes the channel region 33, and a region sandwiched between the cathode region 182 and the anode region 184 of the photodiode 160 becomes the intrinsic region 183. FIG. 23 is a plan view showing a manufacturing step which corresponds to FIG. 16(A). As shown in FIG. 23, the active layer 31 is formed with the source region 32, the channel region 33, and the drain region 34, and the active layer 181 is formed with the cathode region 182, the intrinsic region 183, and the anode region 184.

Further, the inter-layer insulating film 45 made up of silicon oxide is deposited so as to coat the entire glass substrate 15 including the active layer 31 and the active layer 181. The inter-layer insulating film 45 has a film thickness of, for example, 300 nm and deposited by atmospheric pressure CVD using TEOS as a source gas, or some other means. Next, the inter-layer insulating film 45 is opened with the contact holes 47 that respectively reach the source region 32, the drain region 34, the cathode region 182, and the anode region 184. At this time, a contact hole (not shown) that reaches the gate electrode 21 is simultaneously opened.

As shown in FIG. 16(B), an aluminum film (not shown) is deposited by means of sputtering so as to coat the entire surface of the glass substrate 15 including the inside of the contact hole 47, and the aluminum film is patterned by means of photolithography. Then, the substrate 15 is heat-treated. Therefore, the source electrode 41 ohmically connected with the source region 32, the drain electrode 42 ohmically connected with the drain region 34, the cathode electrode 191 ohmically connected with the cathode region 182 of the photodiode 160, and the anode electrode 192 ohmically connected with the anode region 184 thereof are respectively formed via the contact holes 47. This results in formation of the TFT 10 including the gate electrode 21 and the active layer 31, and the photodiode 160 with the PIN structure including the light-blocking film 171 and the active layer 181. A protective film (not shown) made up of a silicon nitride film is deposited by means of plasma CVD so as to coat the entire glass substrate 15 including the TFT 10 and the photodiode 160. In such a manner, the semiconductor device 100 including the TFT 10 and the photodiode 160 with the PIN structure is manufactured.

### 2.3 Electric Characteristics of Semiconductor Device

As for the TFT 10 included in the semiconductor device 100 manufactured by the foregoing manufacturing method, its carrier mobility was measured, to obtain a value as high as 350 cm²/V·s. Further, as for the photodiode 160 formed in the second silicon region 130c2 and a photodiode having the same structure as that of the photodiode 160 and formed in the first silicon region 130c1, respective on/off ratios of those were measured. As a result, the on/off ratio of the photodiode 160 was 5.4 times as large as that of the photodiode formed in the first silicon region 130c1.

### 2.4 Effect

According to the manufacturing method of the present embodiment, the gate electrode 21 formed with the radiation portion 22 on the periphery thereof and the light-blocking film 171 are previously formed, and on the crystalline silicon film 130b formed above those films, the crystallization step is performed twice in total, including one-time laser annealing, thereby to allow formation of the crystalline silicon film 130c including the first silicon region 130c1 and the second silicon region 130c2 with different average grain sizes. This can simplify the manufacturing method for the semiconductor device 100 by use of the first silicon region 130c1 and the second silicon region 130c2. Further, the first silicon region 130c1 is formed so as to be located above the gate electrode 21 and the radiation portion 22, and the second silicon region 130c2 is formed so as to be located above the light-blocking film 171. As thus described, only deciding whether to provide the radiation portion 22 can lead to selection of optimum silicon regions respectively for the TFT 10 and the photodiode 160 out of the first and second silicon regions 130c1, 130c2.

Further, since the average grain sizes are different between the first silicon region 130c1 and the second silicon region 130c2 of the crystalline silicon film 130c formed by the manufacturing method of the present embodiment, electric characteristics, such as carrier mobilities, are also different therebetween. For example, forming the TFT 10 with the first silicon region 130c1 serving as the active layer can improve gate voltage-on current characteristics, and forming the photodiode 160 with the PIN structure, with the second silicon region 130c2 serving as the active layer, can increase an on/off ratio.

### 3. Modified Example Common Between First and Second Embodiments

In the first and second embodiments, the nickel film 35 to serve as a catalyst was vapor-deposited on the surfaces of the amorphous silicon films 30a, 130a so as to promote crystallization of the amorphous silicon films 30a, 130a. However, in place of the nickel film 35, there may be vapor-deposited a metal film made up of any element out of iron (Fe), cobalt (Co), germanium (Ge), ruthenium (Ru), rhodium (Rh), palladium (Pd), osmium (Os), iridium (Ir), platinum (Pt), copper (Cu), and gold (Au), or a metal film containing a plurality of elements out of those elements.

In the first and second embodiments, the metal film containing the catalytic elements for promoting crystallization of the amorphous silicon films 30a, 130a was vapor-deposited on the surfaces of the amorphous silicon films 30a, 130a by means of resistive heating. However, in place of resistive heating, a solution containing the catalytic elements may be applied to the surfaces of the amorphous silicon films 30a, 130a by a spinner technique, or a metal film containing the catalytic elements may be vacuum vapor-deposited. Using these methods can facilitate addition of the catalytic elements to the surfaces of the amorphous silicon films 30a, 130a.

In the first and second embodiments, the descriptions were given by taking the amorphous silicon films 30a, 130a and the crystalline silicon films 30b, 30c, 130b, 130c for examples as the amorphous semiconductor films and the crystalline semiconductor films. However, the amorphous semiconductor film and the crystalline semiconductor film are not restricted to these and may, for example, be an amorphous silicon-germanium film and a crystalline silicon-germanium film.

In the first and second embodiments, the descriptions were given in that the silicon films obtained by crystallizing the amorphous silicon films 30a, 130a were the crystalline silicon films 30b, 30c, 130b, 130c. Examples of these crystalline silicon films 30b, 30c, 130b, 130c include polycrystalline silicon films, continuous grain silicon films, and the like.

### 4. First Liquid Crystal Display Device

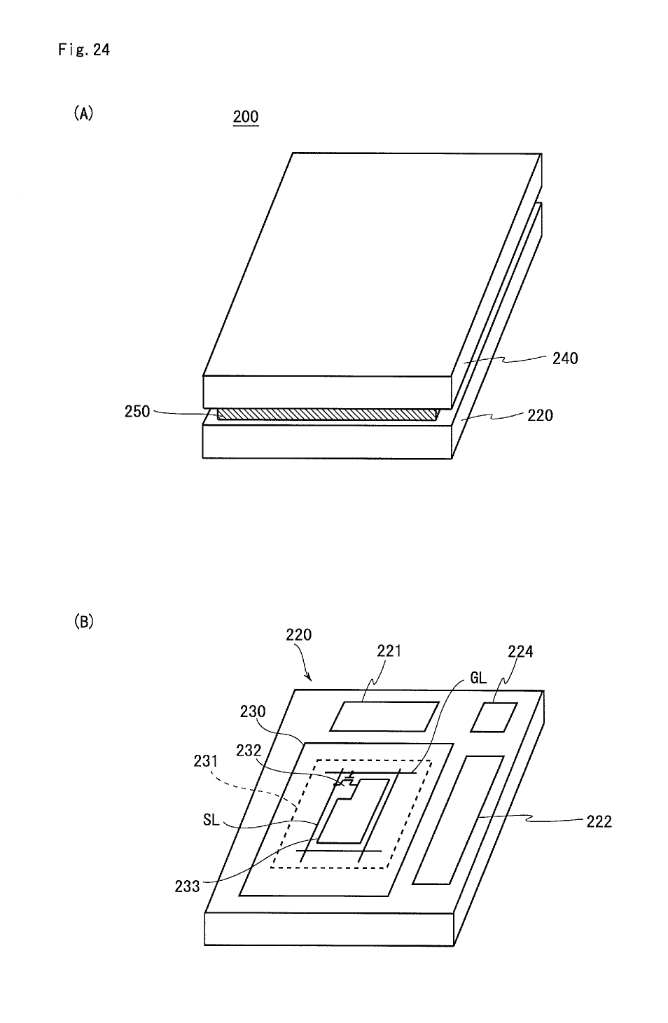

FIG. 24(A) is a perspective view showing a liquid crystal panel 200 of an active matrix-type liquid crystal display device provided with the semiconductor device 1 according to the first embodiment, and FIG. 24(B) is a perspective view showing a TFT substrate 220 included in the liquid crystal panel 200 shown in FIG. 24(A). As shown in FIG. 24(A), the liquid crystal panel 200 is a full-monolithic panel including two glass substrates 220, 240 which are arranged as opposed to each other, and a sealing member 250 for sealing a liquid crystal layer (not shown) held between the two glass substrates 220 and 240. Of the two glass substrates 220, 240, a glass substrate on which a plurality of pixel formation portions including TFTs are formed in a matrix shape is referred to as the TFT substrate 220, and a glass substrate which is arranged as opposed to the TFT substrate 220 and on which a color filter and the like are formed is referred to as the CF substrate 240.

As shown in FIG. 24(B), the TFT substrate 220 includes an image display portion 230 formed with a plurality of pixel formation portions 231. The pixel formation portion 231 is formed with a TFT 232 that functions as a switching device, and a pixel electrode 233 connected to the TFT 232 . A picture-frame portion outside the image display portion 230 is provided with a source driver 221, a gate driver 222, and a power supply circuit 224 for supplying a power supply voltage to those (hereinafter, these may be collectively referred to as a “peripheral circuit”). The gate driver 222 outputs a control signal that controls the timing for turning on/off the TFT 232 to a gate wire GL, and the source driver 221 outputs to a source wire SL an image signal that displays an image on the pixel formation portion 231 and a control signal that controls the timing for outputting the image signal.

The gate wire GL is sequentially activated to bring the TFT 232, connected to the activated gate wire GL, into an on-state, and hence the image signal given to the source wire SL is given to the pixel electrode 233 via the TFT 232. The pixel electrode 233 forms a pixel capacitance along with a common electrode (not shown) formed on the CF substrate 240, to hold the given image signal. This results in that backlight emitted from a backlight unit (not shown) provided on the under surface of the TFT substrate 220 is transmitted through the pixel formation portion 231 in accordance with the image signal, and an image is displayed on the image display portion 230 of the liquid crystal panel 200.

In such a liquid crystal panel 200, using the TFT 60, included in the semiconductor device 1 shown in FIG. 1, as the TFT 232 of the pixel formation portion 231 makes a variation in threshold voltage of the TFT 60 small, and can thus reduce variations in brightness and color of the pixel formation portion 231. This can stabilize display of the liquid crystal display device.

Further, constituting the peripheral circuit by use of the TFT 10 included in the semiconductor device 1 can lead to high operation speeds of the source driver 221, the gate driver 222, and the like. Since this can make a circuit size of the peripheral circuit small, the picture-frame portion of the liquid crystal panel 200 is narrow, so as to allow reduction in size of the liquid crystal panel 200. Further, performance and image quality of the liquid crystal display device can be enhanced.

### 5. Second Liquid Crystal Display Device

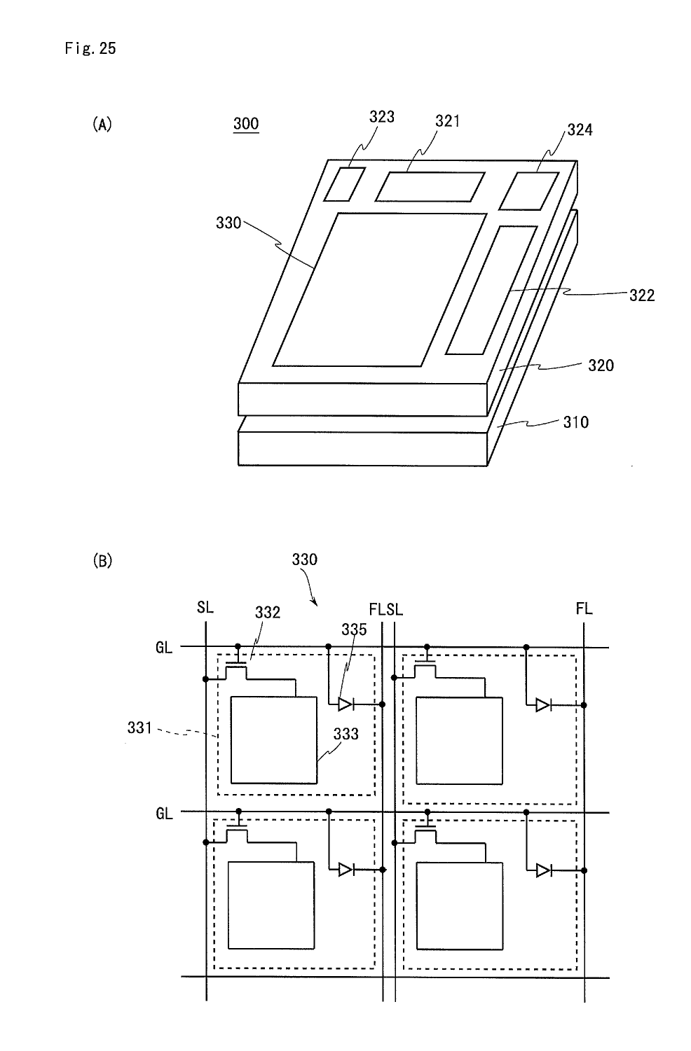

FIG. 25(A) is a perspective view showing a liquid crystal panel 300 of an active matrix-type liquid crystal display device with a touch panel function which is provided with the semiconductor device 100 according to the second embodiment, and FIG. 25 (B) is a circuit diagram showing a configuration of an image display portion 330 included in a TFT substrate 320 of the liquid crystal panel 300 shown in FIG. 25(A). As shown in FIG. 25(A), the liquid crystal panel 300 is a full-monolithic panel, and includes the TFT substrate 320 and a CF substrate (not shown) which are arranged as opposed to each other, as does the liquid crystal panel 200 shown in FIG. 24(A). Further, the under surface of the TFT substrate 320 is provided with a backlight unit 310 so as to be opposed to the TFT substrate 320.

In the vicinity of the center of the TFT substrate 320, the image display portion 330 is formed which is made up of a plurality of pixel formation portions 331 and on which an image is displayed. A picture-frame portion outside the image display portion 330 is provided with a source driver 321, a gate driver 322, a position detection circuit 323 for detecting a touched position on the liquid crystal panel 300 based on the intensity of the light detected by a photodiode 335, and a power supply circuit 324 for supplying a power supply voltage to those (hereinafter, those may be collectively referred to as a “peripheral circuit”).

As shown in FIG. 25(B), the TFT substrate 320 is formed with a plurality of pixel formation portions 331, a plurality of gate wires GL, a plurality of source wires SL, and a plurality of sensor wires FL. The sensor wire FL extends in a parallel direction to the source wire SL, and intersects with the gate wire GL. The pixel formation portion 331 includes the TFT 332 and the photodiode 335. The TFT 332 functions as a switching device, and the photodiode 335 receives light having been emitted from the backlight unit 310, reflected by a finger or a stylus pen and incident on the pixel formation portion 331.

The photodiode 335 is arranged in the vicinity of an intersection point between the gate wire GL and the sensor wire FL, and the anode electrode of the photodiode 335 is connected to the gate wire GL, and the cathode electrode is connected to the sensor wire FL. When a predetermined voltage is applied to the gate wire GL, a current with a magnitude in accordance with intensity of the light incident on the photodiode 335 flows from the gate wire GL to the sensor wire FL via the photodiode 335. The position detection circuit 323 detects a value of the current flowing through the sensor wire FL, thereby to detect the intensity of the light received by the photodiode 335, to detect the touched position on the CF substrate.

In such a liquid crystal panel 300, using the photodiode 160 included in the semiconductor device 100 shown in FIG. 12 as the photodiode 335 of the pixel formation portion 331 makes the on/off ratio large, thereby to allow detection of the touched position with high accuracy. Further, the photodiode 335 has the light-blocking film 171 formed on the TFT substrate 320. The light-blocking film 171 blocks light emitted by the backlight unit 310 so as to prevent the light from being directly incident on the photodiode 160. Thereby, the light received by the photodiode 335 is only light reflected by a finger or the like having touched the surface of the CF substrate, and hence the position detection circuit 323 can more accurately detect the touched position.

Further, when the peripheral circuit is configured using the TFT 10 included in the semiconductor device 100, the operation speed of the peripheral circuit such as the source driver 321 and the gate driver 322 can be made high. Since this can make circuit scales of gate driver 322 and the source driver 321 small, the picture-frame portion of the liquid crystal panel 300 is narrow, so as to allow reduction in size of the liquid crystal panel 300. Further, performance and image quality of the liquid crystal display device can be enhanced.

Moreover, using the TFT 60, included in the semiconductor device 1 shown in FIG. 1, as the TFT 332 included in the pixel formation portion 331 of the liquid crystal panel 300 makes a variation in threshold voltage small, and can thus reduce variations in brightness and color of the pixel formation portion 331. This can stabilize display of the liquid crystal display device.

It is to be noted that the descriptions were given by taking the liquid crystal display device for an example as the display device to which the semiconductor devices 1, 100 shown in FIGS. 1 and 12 are applicable. However, the semiconductor devices 1, 100 are also applicable to a display device such as an organic EL (Electroluminescence) display device and a plasma display device.

### INDUSTRIAL APPLICABILITY

The present invention is suitable for an active matrix-type liquid crystal display device, and an active matrix-type liquid crystal display device with a touch panel function, and particularly suitable for a switching device formed in a pixel formation portion of the device, a transistor constituting a drive circuit for driving the pixel formation portion, or a photodiode for detecting a touched position.

### DESCRIPTION OF REFERENCE CHARACTERS

1, 100: SEMICONDUCTOR DEVICE
5: LASER BEAM
10: (FIRST) THIN FILM TRANSISTOR (TFT)
15: GLASS SUBSTRATE (INSULATING SUBSTRATE)
20: MOLYBDENUM FILM (METAL FILM)
21, 71: GATE ELECTRODE
22: RADIATION PORTION
25: GATE INSULATING FILM (INSULATING FILM)
30a, 130a: AMORPHOUS SILICON FILM
30b, 130b: (FIRST) CRYSTALLINE SILICON FILM
30c, 130c: (SECOND) CRYSTALLINE SILICON FILM
30c1, 130c1: FIRST SILICON REGION
30c2, 130c2: SECOND SILICON REGION
31, 81, 181: ACTIVE LAYER
60: (SECOND) THIN FILM TRANSISTOR (TFT)
160: PHOTODIODE
171: LIGHT BLOCKING FILM
200, 300: LIQUID CRYSTAL PANEL
230, 330: IMAGE DISPLAY PORTION
221 to 224, 321 to 324: PERIPHERAL CIRCUIT

1. A manufacturing method for a crystalline semiconductor film, to form crystalline semiconductor films including a plurality of semiconductor regions with different average grain sizes on an insulating substrate, the method comprising:
a step of depositing a metal film on the insulating substrate;
a step of patterning the metal film to form a first metal pattern and a second metal pattern with a smaller area than that of the first metal pattern;
a step of depositing an insulating film so as to coat the first and second metal patterns;
a step of depositing an amorphous semiconductor film on the insulating substrate;
a first crystallization step of crystallizing the amorphous semiconductor film, to form a first crystalline semiconductor film; and
a second crystallization step of crystallizing the first crystalline semiconductor film, to form a second crystalline semiconductor film, wherein
the second crystalline semiconductor film includes
a first semiconductor region located above the first metal pattern and having substantially the same average grain size as an average grain size of the first crystalline semiconductor film, and
a second semiconductor region located above the second metal pattern and having a larger average grain size than the average grain size of the first semiconductor region.

2. The manufacturing method for a crystalline semiconductor film according to claim 1, wherein the second crystallization step includes a step of irradiating the first crystalline semiconductor film with a laser beam.

3. The manufacturing method for a crystalline semiconductor film according to claim 1, wherein the first metal pattern includes a third metal pattern, and a fourth metal pattern surrounding the third metal pattern.

4. The manufacturing method for a crystalline semiconductor film according to claim 2, wherein a wavelength of the laser beam is from 126 to 370 nm.

5. The manufacturing method for a crystalline semiconductor film according to claim 2, wherein the laser beam is outputted from a pulse oscillating excimer laser.

6. The manufacturing method for a crystalline semiconductor film according to claim 2, wherein
the laser beam is a substantially linear beam, and
the second crystallization step is to step-scan the laser beam in a short-axial direction of a beam shape.

7. The manufacturing method for a crystalline semiconductor film according to claim 6, wherein a width of the first metal pattern is larger than a length in the short-axial direction of the laser beam.

8. The manufacturing method for a crystalline semiconductor film according to claim 1, wherein the first crystallization step includes a step of heating the amorphous semiconductor film at a predetermined temperature to be grown by solid phase epitaxy, so as to form the first crystalline semiconductor film.

9. The manufacturing method for a crystalline semiconductor film according to claim 8, wherein the predetermined temperature is from 500 to 700° C.

10. The manufacturing method for a crystalline semiconductor film according to claim 8, wherein the first crystallization step further includes a step of adding catalytic elements for promoting crystallization of the amorphous semiconductor film to the surface of the amorphous semiconductor film.

11. The manufacturing method for a crystalline semiconductor film according to claim 10, wherein the catalytic element contains at least one element selected from the group consisting of iron, cobalt, nickel, germanium, ruthenium, rhodium, palladium, osmium, iridium, platinum, copper, and gold.

12. The manufacturing method for a crystalline semiconductor film according to claim 10, wherein the step of adding the catalytic elements includes the step of forming a film that contains the catalytic elements with a concentration of 1E10 to 1E12 atoms/cm² on the surface of the amorphous semiconductor film.

13. The manufacturing method for a crystalline semiconductor film according to claim 1, wherein the amorphous semiconductor film is an amorphous silicon film, and the first and second crystalline semiconductor films are crystalline silicon films.

14. The manufacturing method for a crystalline semiconductor film according to claim 1, wherein the metal film contains refractory metal elements, and the insulating film includes at least any of a silicon oxide film, a silicon nitride film, and a silicon oxynitride film.

15. (canceled)

16. A semiconductor device, comprising a thin film transistor in which the crystalline semiconductor film, formed by the manufacturing method for a crystalline semiconductor film according to claim 1, serves as an active layer.

17. The semiconductor device according to claim 16, wherein
the crystalline semiconductor film includes a first semiconductor region, and a second semiconductor region having a smaller average grain size than that of the first semiconductor region,
the thin film transistor includes a first thin film transistor, and a second thin film transistor with different electric characteristics from those of the first thin film transistor, and
the first semiconductor region serves as an active layer in the first thin film transistor, and the second semiconductor region serves as an active layer in the second thin film transistor.

18. The semiconductor device according to claim 16, further comprising a photodiode, wherein
the crystalline semiconductor film includes a first semiconductor region, and a second semiconductor region having a smaller average grain size than that of the first semiconductor region, and
the first semiconductor region serves as an active layer in the thin film transistor, and the second semiconductor region serves as an active layer in the photodiode.

19. The semiconductor device according to claim 18, wherein the photodiode further includes a light blocking film made up of a metal pattern and formed in between the active layer and the insulating substrate.

20. A display device, comprising the semiconductor device according to claim 17, an image display portion, and a peripheral circuit required for driving the image display portion, wherein
the peripheral circuit includes the first thin film transistor of the semiconductor device, and
the image display portion includes the second thin film transistor of the semiconductor device.

21. A display device, comprising:
the semiconductor device according to claim 17;
a photosensor;
an image display portion; and
a peripheral circuit required for driving the image display portion; wherein
the photosensor includes the photodiode of the semiconductor device;
the peripheral circuit includes the first thin transistor of the semiconductor device, and
the image display portion includes the second thin film transistor of the semiconductor device.
